(19) United States
(12) Patent Application Publication
(10) Pub. No.: US 2019/0259351 A1
(43) Pub. Date: Aug. 22, 2019

(54) FLEXIBLE ELECTRONIC DEVICE INCLUDING OPTICAL SENSOR AND METHOD OF OPERATING SAME

(71) Applicant: Samsung Electronics Co., Ltd., Suwon-si (KR)

(72) Inventors: Heewoong YOON, Suwon-si (KR); Jongah KIM, Suwon-si (KR); Changsoo KIM, Suwon-si (KR); Donghan LEE, Suwon-si (KR); Jeongho CHO, Suwon-si (KR); Yoomi TAK, Suwon-si (KR); Sangmin HWANG, Suwon-si (KR); Jeongmin PARK, Suwon-si (KR)

(21) Appl. No.: 16/281,506

(22) Filed: Feb. 21, 2019

(30) Foreign Application Priority Data
Feb. 21, 2018 (KR) 10-2018-0020785

(51) Int. Cl. G09G 5/10; H01L 27/32; H01L 51/52; H01L 51/00; G06F 3/14; G06F 1/16

(52) U.S. Cl. CPC G09G 5/10; H01L 27/3267; H01L 27/3269; H01L 51/5275; H01L 51/0097; G09G 2380/02; G06F 1/1652; H01L 2251/5338; G09G 2360/14; G09G 2320/0626; G06F 3/1423

(57) ABSTRACT

An electronic device is provided. The electronic device includes an optical sensor including a light-receiving module and a light-emitting module, a processor electrically connected to the optical sensor, and a housing including a first region, a second region, and a bendable region connecting the first region and the second region, the housing being disposed such that at least a portion of the optical sensor in the first region is exposed through one surface of the first region, wherein a light transmission region is included in at least a portion of the second region such that light related to sensing by the optical sensor passes through the second region in a state in which the one surface of the first region and one surface of the second region face each other according to bending of the bendable region.

### CROSS-REFERENCE TO RELATED APPLICATION(S)

This application is based on and claims priority under 35 U.S.C. § 119(a) of a Korean patent application Serial number 10-2018-0020785, filed on Feb. 21, 2018, in the Korean Intellectual Property Office, the disclosure of which is incorporated by reference herein in its entirety.

### BACKGROUND

### 1. Field

The disclosure relates to a flexible electronic device including an optical sensor and a method of operating the same.

### 2. Description of Related Art

With the development of digital technology, electronic devices are provided in various forms such as smart phones, tablet personal computers (PCs), and personal digital assistants (PDAs). Electronic devices are developed in a form which can be worn on users to improve portability and accessibility of the user.

The electronic device may include a display for displaying an image. The display may be a touch-sensitive display, and the electronic device may detect user input through the display. Further, the electronic device may include various optical sensors for sensing physical quantities and environmental changes, and may perform various functions on the basis of a signal output from such an optical sensor. The optical sensor may include both a light-emitting module (or a light source) and a light-receiving module or only the light-receiving module like an illumination sensor.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a flexible electronic device including an optical sensor and a method of operating the same.

The electronic device may be designed to be flexible in a foldable form. When the electronic device is in a folded state, the optical sensor may be hidden by part of the electronic device and thus may operate abnormally. The electronic device may be designed to further include an additional optical sensor which can be used in the folded state, which increases the cost of manufacturing the electronic device.

Another aspect of the disclosure is to provide a flexible electronic device including an optical sensor which can be used when the electronic device is in a folded state without installation of an additional optical sensor and a method of operating the same.

Another aspect of the disclosure is to provide a flexible electronic device including an optical sensor of which performance is maintained even in an unfolded state of the electronic device and a method of operating the same.

Additional aspects will be set forth in part in the description which follows and, in part, will be apparent from the description, or may be learned by practice of the presented embodiments.

In accordance with an aspect of the disclosure, an electronic device is provided. The electronic device includes an optical sensor including a light-receiving module and a light-emitting module, a processor and a housing including a first region, a second region, and a bendable region connecting the first region and the second region, the housing being disposed such that the optical sensor in the first region is exposed through a first surface of the first region, wherein the second region includes a light transmission region to pass light to the optical sensor when the first surface of the first region and a second surface of a second region face each other based on a bending of the bendable region.

In accordance with another aspect of the disclosure, a flexible electronic device is provided. The flexible electronic device includes an optical sensor according to various embodiments provides a structure in which at least a portion of an optical sensor located in a first region uses a light transmission region formed in a second region in a state in which the first region and the second region of the electronic device are folded to face each other (that is, a folded state) without addition of any optical sensor, thereby obtaining an effect of reducing costs and facilitating design of the structure. Further, a flexible electronic device including an optical sensor according to various embodiments performs an operation flow of increasing the intensity of output of a light-emitting module of the first region in the folded state, thereby preventing deterioration of sensing performance due to a decrease in the amount of light when at least the portion of the optical sensor located in the first region uses the light transmission region of the second region.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device within a network environment according to an embodiment of the disclosure;

FIG. 2A illustrates a first folded state of a flexible electronic device according to an embodiment of the disclosure;

FIG. 2B illustrates an unfolded state of the flexible electronic device of FIG. 2A according to an embodiment of the disclosure;

FIG. 2C illustrates a second folded state of the flexible electronic device of FIG. 2A according to an embodiment of the disclosure;

FIGS. 3A and 3B are cross-sectional views of a light transmission region according to various embodiments of the disclosure;

FIGS. 3C, 3D, 3E, and 3F are cross-sectional views of a plate included in the light transmission region according to various embodiments of the disclosure;

FIGS. 4A and 4B illustrate an unfolded state of an electronic device according to various embodiments of the disclosure;

FIG. 4C illustrates a folded state of the electronic device of FIG. 4A according to an embodiment of the disclosure;

FIG. 4D is a cross-sectional view schematically illustrating the folded state of the electronic device of FIG. 4A according to an embodiment of the disclosure;

FIGS. 5A and 5B illustrate an unfolded state of an electronic device according to various embodiments of the disclosure;

FIG. 5C illustrates a folded state of the electronic device of FIG. 5A according to an embodiment of the disclosure;

FIG. 5D is a cross-sectional view schematically illustrating the folded state of the electronic device of FIG. 5A according to an embodiment of the disclosure;

FIG. 6 is a cross-sectional view schematically illustrating a folded state of the electronic device according to an embodiment of the disclosure;

FIG. 7 is a block diagram illustrating an electronic device according to an embodiment of the disclosure;

FIG. 8 illustrates a method for determining proximity of an external object according to an embodiment of the disclosure;

FIG. 9 illustrates a method for determining proximity of an external object and performing an operation based on a determination result according to an embodiment of the disclosure;

FIG. 10 illustrates a method for determining proximity of an external object according to an embodiment of the disclosure; and

FIG. 11 illustrates a method for determining proximity of an external object according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that various embodiments of the disclosure and the terms used therein are not intended to limit the technological features set forth herein to particular embodiments and include various changes, equivalents, or replacements for a corresponding embodiment. In describing the drawings, similar reference numerals may be used to designate similar constituent elements. It is to be understood that a singular form of a noun corresponding to an item may include one or more of the things, unless the relevant context clearly indicates otherwise. As used herein, phrases such as “A or B”, “at least one of A and B”, “at least one of A or B”, “A, B, or C”, “at least one of A, B, and C”, and “at least one of A, B, or C”, may include all possible combinations of the items enumerated together in a corresponding one of the phrases. As used herein, terms such as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element. The expression “configured to” as used in various embodiments of the disclosure may be interchangeably used with, for example, “suitable for”, “having the capacity to”, “designed to”, “adapted to”, “made to”, or “capable of” in terms of hardware or software, according to circumstances. Alternatively, in some situations, the expression “device configured to” may mean that the device, together with other devices or components, “is able to”.

An electronic device according to various embodiments disclosed herein may be various types of devices. The electronic device may, for example, include at least one of a portable communication device (e.g., smartphone) a computer device, a portable multimedia device, a portable medical device, a camera, a wearable device, and a home appliance. The electronic device according to an embodiment of the disclosure is not limited to the above described devices.

According to various embodiments, the wearable device may include at least one of an accessory type (e.g., a watch, a ring, a bracelet, an anklet, a necklace, a glasses, a contact lens, or a head-mounted device (HMD)), a fabric or clothing integrated type (e.g., an electronic clothing), a body-mounted type (e.g., a skin pad, or tattoo), and a bio-implantable type (e.g., an implantable circuit). In some embodiments, the electronic device may include at least one of, for example, a television, a digital video disc (DVD) player, an audio, a refrigerator, an air conditioner, a vacuum cleaner, an oven, a microwave oven, a washing machine, an air cleaner, a set-top box, a home automation control panel, a security control panel, a television (TV) box (e.g., Samsung HomeSync™, Apple TV™, or Google TV™), a game console (e.g., Xbox™ and PlayStation™), an electronic dictionary, an electronic key, a camcorder, and an electronic photo frame.

In other embodiments, the electronic device may include at least one of various medical devices (e.g., various portable medical measuring devices (a blood glucose monitoring device, a heart rate monitoring device, a blood pressure measuring device, a body temperature measuring device, etc.), a magnetic resonance angiography (MRA), a magnetic resonance imaging (MRI), a computed tomography (CT) machine, and an ultrasonic machine), a navigation device, a global positioning system (GPS) receiver, an event data recorder (EDR), a flight data recorder (FDR), a Vehicle Infotainment Devices, an electronic devices for a ship (e.g., a navigation device for a ship, and a gyro-compass), avionics, security devices, an automotive head unit, a robot for home or industry, an automatic teller's machine (ATM) in banks, point of sales (POS) in a shop, or internet device of things (e.g., a light bulb, various sensors, electric or gas meter, a sprinkler device, a fire alarm, a thermostat, a streetlamp, a toaster, a sporting goods, a hot water tank, a heater, a boiler, etc.). According to some embodiments, an electronic device may include at least one of a part of furniture or a building/structure, an electronic board, an electronic signature receiving device, a projector, and various types of measuring instruments (e.g., a water meter, an electric meter, a gas meter, a radio wave meter, and the like). In various embodiments, the electronic device may be flexible, or may be a combination of one or more of the aforementioned various devices. The electronic device according to an embodiment of the disclosure is not limited to the above described devices. In the disclosure, the term “user” may indicate a person using an electronic device or a device (e.g., an artificial intelligence electronic device) using an electronic device.

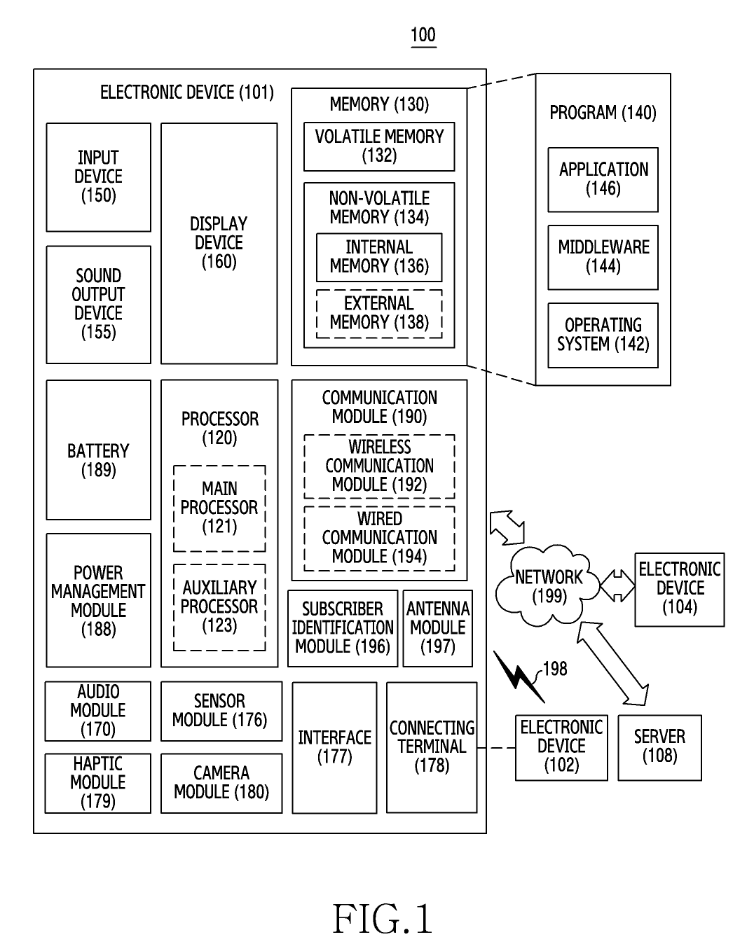

FIG. 1 is a block diagram illustrating an electronic device within a network environment according to an embodiment of the disclosure.

Referring to FIG. 1, the electronic device 101 may communicate with an electronic device 102 through a first network 198 (for example, a short-range wireless communication network) or may communicate with an electronic device 104 or a server 108 through a second network 199 (for example, a long-range wireless communication network) in the network environment 100. According to an embodiment, the electronic device 101 may communicate with the electronic device 104 through the server 108. According to an embodiment, the electronic device 101 may include a processor 120, a memory 130, an input device 150, a sound output device 155, a display device 160, an audio module 170, a sensor module 176, an interface 177, a haptic module 179, a camera module 180, a power management module 188, a battery 189, a communication module 190, a subscriber identification module 196, or an antenna module 197. In some embodiments, the electronic device 101 may omit at least one of the elements, or may further include one or more other elements. In some embodiments, some of the elements may be implemented as a single integrated circuit. For example, the sensor module 176 (for example, a finger sensor, an iris sensor, or an illumination sensor) may be implemented while being embedded in the display device 160 (for example, a display).

The processor 120 may control, for example, at least one other element (for example, a hardware or software element) of the electronic device 101 connected to the processor 120 by executing software (for example, the program 140) and perform various data processing or calculations. According to an embodiment, as a portion of the data processing or calculations, the processor 120 may load instructions or data received from another element (for example, the sensor module 176 or the communication module 190) into volatile memory 132, process the instructions or data stored in the volatile memory 132, and store the resultant data in nonvolatile memory 134. According to an embodiment, the processor 120 may include a main processor 121 (for example, a central processing unit or an application processor) and an auxiliary processor 123 (for example, a graphic processing unit, an image signal processor, a sensor hub processor, or a communication processor) which operate independently from the main processor or together with the main processor. Additionally or alternatively, the auxiliary processor 123 may use lower power than the main processor 121 or may be configured to be specialized for a predetermined function. The auxiliary processor 123 may be implemented separately from or as a portion of the main processor 121.

The auxiliary processor 123 may control at least some of functions or states related to at least one element (for example, the display device 160, the sensor module 176, or the communication module 190) of the electronic device 101 instead of the main processor 121 while the main processor 21 is in an inactive (for example, sleep) state or together with the main processor 121 while the main processor 121 is in an active (for example, application execution) state. According to an embodiment, the auxiliary processor 123 (for example, an image signal processor or a communication processor) may be implemented as a portion of other functionally related elements (for example, the camera module 180 or the communication module 190).

The memory 130 may store various pieces of data used by at least one element of the electronic device 101 (for example, the processor 120 or the sensor module 176). The data may include, for example, software (for example, the program 140) and input data or output data for instructions related thereto. The memory 130 may include volatile memory 132 or nonvolatile memory 134.

The program 140 may be stored in the memory 130 as software and may include, for example, an operating system 142, middleware 144, or an application 146.

The input device 150 may receive instructions or data to be used by the element (for example, the processor 120) of the electronic device 101 from the outside of the electronic device 101 (for example, the user). The input device 150 may include, for example, a microphone, a mouse, or a keyboard.

The sound output device 155 may output a sound signal to the outside of the electronic device 101. The sound output device 155 may include, for example, a speaker or a receiver. The speaker may be used for general purposes, such as reproducing multimedia or recording and the receiver may be used for receiving an incoming call. According to an embodiment, the receiver may be implemented separately from the speaker or as a portion of the speaker.

The display device 160 may visually provide information to the outside of the electronic device 101 (for example, the user). The display device 160 may include, for example, a display, a hologram device, a projector, and a control circuit for controlling a corresponding device. According to an embodiment, the display device 160 may include a touch circuit configured to detect a touch or a sensor circuit (for example, a pressure sensor) configured to measure the intensity of force generated by the touch.

The electronic device 101 may be designed to be flexible. According to an embodiment, the electronic device 101 is a flexible plate substantially including both sides disposed on opposite surfaces, and may include, for example, a first region, a second region, and a bendable region (or a hinge region), which is disposed between the first region and the second region and is capable of being bent, although not illustrated. The second region may be rotated with respect to the first region by the bendable region. When the second region is capable of being rotated in a clockwise (CW) direction or a counterclockwise (CCW) direction, the electronic device 101 may be defined to be in an unfolded state. When the second region moves to a position at which CW or CCW rotation cannot be performed, the electronic device 101 may be defined to be in a folded state. According to an embodiment, the display device 160 may include a display disposed along at least a portion of the first region, the second region, and the bendable region such that the display device 160 is exposed in the folded state.

According to an embodiment, in the folded state, an optical element (for example, a light source or an optical sensor such as a grip sensor, a proximity sensor, a color sensor, an infrared (IR) sensor, a biometric sensor, or an illumination sensor) included in the first region may be arranged in a portion of the second region. The portion of the second region may be designed as a light transmission region used by the optical element in the folded state.

According to an embodiment, the optical sensor included in the first region may include a first light-emitting module and a first light-receiving module. In the folded state, light output from the first light-emitting module may pass through the light transmission region of the second region and may be emitted to the outside. In the folded state, external light may pass through the light transmission region and flow into the first light-receiving module. The medium layers through which light output from the first light-emitting module passes in the unfolded state and the medium layers through which light output from the first light-emitting module passes in the folded state may be different from each other. Due to the difference between the medium layers, light output from the first light-emitting module may be more attenuated in the folded state. According to an embodiment, the processor 120 may enable the first light-emitting module to drive with first optical output power (or output intensity) in the unfolded state and to drive with second light output power, which is larger than the first light output power, in the folded state. Accordingly, the amount of light (or intensity of light) emitted to the outside in the unfolded state and the amount of light emitted to the outside in the folded state may be substantially constant.

Due to the difference between the medium layers in the unfolded state and the medium layers in the folded state, the amount of light flowing into the first light-receiving module for the same external light may be smaller in the folded state. According to an embodiment, the processor 120 may control a sensing sensitivity (a degree of sensitivity of reaction to external light) for the first light-receiving module differently for the unfolded state and the folded state. For example, the sensing sensitivity may be set as a first sensing sensitivity in the unfolded state and as a second sensing sensitivity, which is more sensitive than the first sensing sensitivity, in the folded state. Accordingly, although the amount of light (or an intensity of light) passing through the corresponding medium layers and flowing into the first light-receiving module in the unfolded state and the amount of light passing through the corresponding medium layers and flowing into the first light-receiving module in the folded state are different from each other, the processor 120 may acquire substantially constant sensing information in the unfolded state and the folded state.

According to some embodiments, the second region may further include a second light-receiving module, and may be designed to have a light transmission region arranged on the first light-emitting module among the first light-emitting module and the first light-receiving module of the first region in the folded state. When executing a corresponding sensing mode, the processor 120 may be designed to selectively use the first light-receiving module and the second light-receiving module, among the first light-emitting module, the first light-receiving module, and the second light-receiving module, in the unfolded state, and to selectively use the first light-emitting module and the second light-receiving module, among the first light-emitting module, the first light-receiving module, and the second light-receiving module, in the folded state. According to an embodiment, the medium layers through which light output from the first light-emitting module passes in the unfolded state and the medium layers through which light output from the first light-emitting module passes in the folded state are different from each other. Due to the difference between the medium layers, the light output from the first light-emitting module may be more attenuated in the folded state. According to an embodiment, the processor 120 may enable the first light-emitting module to drive with higher output power in the folded state compared to the unfolded state. Accordingly, the amount of light (or the intensity of light) emitted to the outside in the unfolded state and the amount of light emitted to the outside in the folded state may be substantially constant. According to various embodiments, the first light-receiving module or the second light-receiving module may be disposed below a rear surface of the display.

According to various embodiments, the first light-receiving module included in the first region and the second light-receiving module included in the second region may be designed to support different sensing modes. The processor 120 may execute a first sensing mode for sensing light in a first wavelength band by selectively using the first light-receiving module and the second light-receiving module, among the first light-emitting module, the first light-receiving module, and the second light-receiving module, in the unfolded state. The processor 120 may execute a second sensing module for sensing light in a second wavelength band, which is at least different from the first wavelength band, by selectively using the first light-emitting module and the second light-receiving module, among the first light-emitting module, the first light-receiving module, and the second light-receiving module.

The audio module 170 may convert a sound into an electrical signal or, conversely, convert an electrical signal into a sound. According to an embodiment, the audio module 170 may acquire a sound through the input device 150 or output a sound through the sound output device 155 or an external electronic device (for example, the electronic device 102) (for example, a speaker or headphones) directly or wirelessly connected to the electronic device 101.

The sensor module 176 may detect an operational state (for example, a power or temperature) of the electronic device 101 or an external environmental state (for example, a user state) and generate an electrical signal or a data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a pressure sensor, a color sensor, an infrared (IR) sensor, a biometric sensor, a temperature sensor, a humidity sensor, or an illumination sensor. According to an embodiment, the sensor module 176 may include at least one sensor capable of acquiring data on the unfolded state or the folded state of the electronic device 101. The sensor may be combined with or included in at least one of the first region, the second region, and the bendable region.

The interface 177 may support one or more predetermined protocols which can be used for directly or wirelessly connecting the electronic device 101 to an external electronic device (for example, the electronic device 102). According to an embodiment, the interface 177 may include a high-definition multimedia interface (HDMI), a universal serial bus (USB) interface, a secure digital (SD) card interface, or an audio interface.

A connection terminal 178 may include a connector which physically connects the electronic device 101 to the external electronic device (for example, the electronic device 102). According to an embodiment, the connection terminal 178 may include, for example, an HDMI connector, a USB connector, an SD card connector, or an audio connector (for example, a headphone connector).

The haptic module 179 may convert an electric signal into mechanical stimulation (for example, vibration or motion) or electric stimulation, which the user recognizes through a sense of touch or kinesthesia. According to an embodiment, the haptic module 179 may include, for example, a motor, a piezoelectric element, or an electrical stimulation device.

The camera module 180 may capture a still image and a moving image. According to an embodiment, the camera module 180 may include one or more lenses, image sensors, image signal processors, or flashes.

The power management module 188 may mange the power supplied to the electronic device 101. According to an embodiment, the power management module 188 may be implemented at least in part by, for example, a power management integrated circuit (PMIC).

The battery 189 may supply power to at least one element of the electronic device 101. According to an embodiment, the battery 189 may include, for example, a non-rechargeable primary cell, a rechargeable secondary cell, or a fuel cell.

The communication module 190 may support establishment of a direct (for example, wired) communication channel or a wireless communication channel between the electronic device 101 and the external electronic device (for example, the electronic device 102, the electronic device 104, or the server 108) and communication through the established communication channel. The communication module 190 may include one or more communication processors which operate independently from the processor 120 (for example, the application processor) and support direct (for example, wired) communication or wireless communication. According to an embodiment, the communication module 190 may include a wireless communication module 192 (for example, a cellular communication module, a short-range wireless communication module, or a global navigation satellite system (GNSS) communication module) or a wired communication module 194 (for example, a local area network (LAN) communication module or a power line communication module). Among the communication modules, the corresponding communication module may communicate with the external electronic device through a first network 198 (for example, a short-range communication network such as Bluetooth, wireless fidelity (Wi-Fi), direct or infrared data association (IrDA)) or a second network 199 (for example, a long-range communication network such as a cellular network, Internet, or a computer network (for example, a LAN or wide area network (WAN)). Various types of communication modules may be integrated into one element (for example, a single chip) or may be implemented as a plurality of separate elements (for example, a plurality of chips). The wireless communication module 192 may identify and authenticate the electronic device 101 within a communication network such as the first network 198 or the second network 199 through subscriber information (for example, an international mobile subscriber identification (IMSI)) stored in the subscriber identification module 196.

The antenna module 197 may transmit signals or power to the outside (for example, to an external electronic device) or receive the same from the outside. According to an embodiment, the antenna module 197 may include one or more antennas, and at least one antenna suitable for the communication scheme used for the communication network, such as the first network 198 or the second network 199, may be selected therefrom by, for example, the communication module 190. The signals or power may be transmitted or received between the communication module 190 and the external electronic device through at least one selected antenna.

Some of the elements may be connected to each other through a scheme for communication between peripheral devices (for example, a bus, general purpose input/output (GPIO), a serial peripheral interface (SPI), or a mobile industry processor interface (MIPI)) and may exchange signals (for example, instructions or data) there between.

According to an embodiment, instructions or data may be transmitted or received between the electronic device 101 and the external electronic device 104 through the server 108 connected to a second network 199. Each of the electronic devices 102 and 104 may be a device which is the same type as or a different type from that of the electronic device 101. According to an embodiment, all or some of the operations executed by the electronic device 101 may be executed by one or more of the external electronic devices 102, 104, and 108. For example, when the electronic device 101 performs any function or service automatically or in response to a request from a user or another device, the electronic device 101 may make a request for performing at least some of the functions or services to one or more external electronic devices instead of performing the functions or services by itself, or may additionally make the request. The one or more external electronic devices receiving the request may perform at least some of the requested functions or services or an additional function or service related to the request and may transfer the result thereof to the electronic device 101. The electronic device 101 may provide the result or additionally process the result and provide the processed result as at least a portion of a response to the request. To this end, for example, cloud-computing, distributed- computing, or client-server-computing technology may be used.

The term “module” as used herein may include a unit consisting of hardware, software, or firmware, and may, for example, be used interchangeably with the term “logic”, “logical block”, “component”, “circuit”, or the like. The “module” may be an integrated component, or a minimum unit for performing one or more functions or a portion thereof. For example, according to an embodiment, the module may be implemented in the form of an application-specific integrated circuit (ASIC).

Various embodiments of this document may be implemented as software (for example, the program 140) including one or more instructions stored in a machine (for example, the electronic device 101)-readable storage medium (for example, the internal memory 136 or the external memory 138). For example, a processor (for example, the processor 120) of the device (for example, the electronic device 101) may load at least one of the one or more stored instructions from the storage medium and execute the instructions. This allows the device to perform at least one function according to at least one loaded instruction. The one or more instructions may include code generated by a compiler or code which can be executed by an interpreter. The machine-readable storage medium may be provided in the form of a non-transitory storage medium. The term “non-transitory” means that the storage medium is a tangible device and does not include a signal (for example, an electromagnetic wave) and does not distinguish the case in which data is stored in the storage medium semi-permanently and the case in which data is stored in the storage medium temporarily.

According to an embodiment, a method according to various embodiments of this document may be included and provided in a computer program product. The computer program product may be traded as a product between a seller and a buyer. The computer program product may be distributed in the form of a machine-readable storage medium (for example, a compact disc read-only memory (CD-ROM)) or distributed online (for example, downloaded or uploaded) through an application store (for example, Play Store™) or directly between two user devices (for example, smart phones). If distributed online, at least a portion of the computer program products may be at least temporarily stored in or temporarily generated by the machine-readable storage medium, such as memory of the manufacturer's server, a server of the application store, or a relay server.

According to various embodiments, each of the elements (for example, the module or the program) may include a single entity or a plurality of entities. According to various embodiments, one or more elements or operations of the above-described corresponding elements may be omitted, or one or more other elements or operations may be added. Alternatively or additionally, a plurality of elements (for example, the module or the program) may be integrated into a single element. In this case, the integrated elements may perform one or more functions of each of the plurality of elements in the same way as or a similar way to that performed by the corresponding element of the plurality of elements before the integration. According to various embodiments, operations performed by the module, the program, or another element may be performed sequentially, in parallel, repeatedly, or heuristically, sequences of one or more of the operations may be changed or omitted, or one or more other operations may be added.

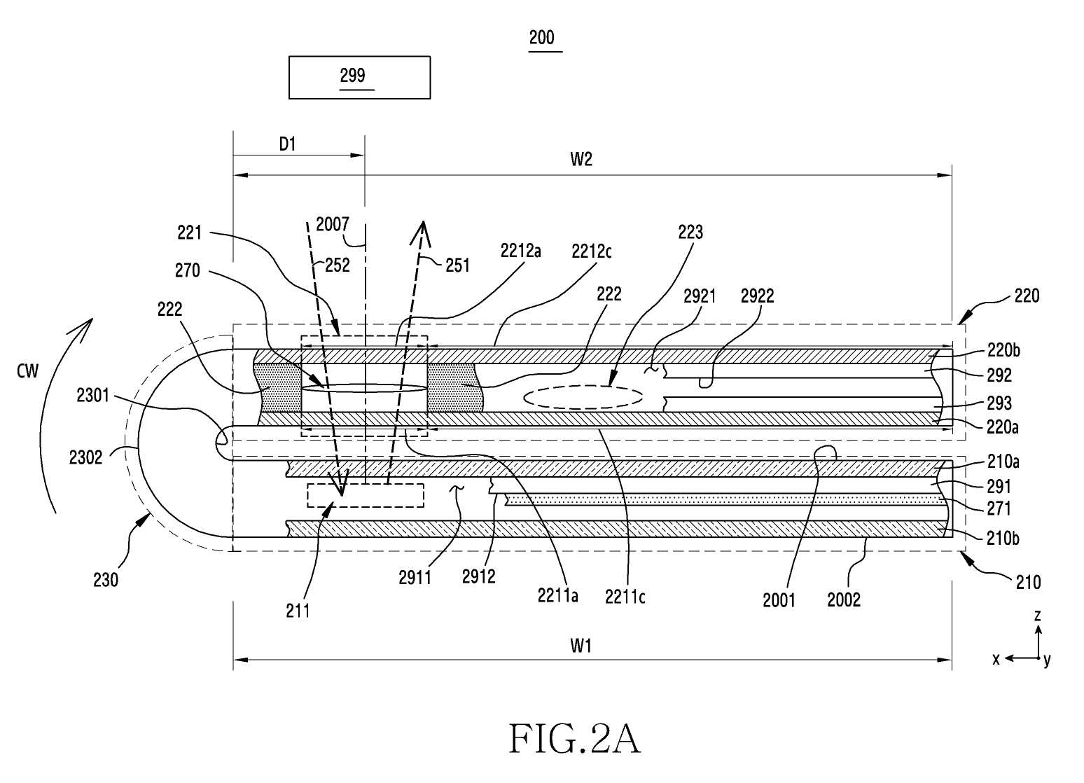

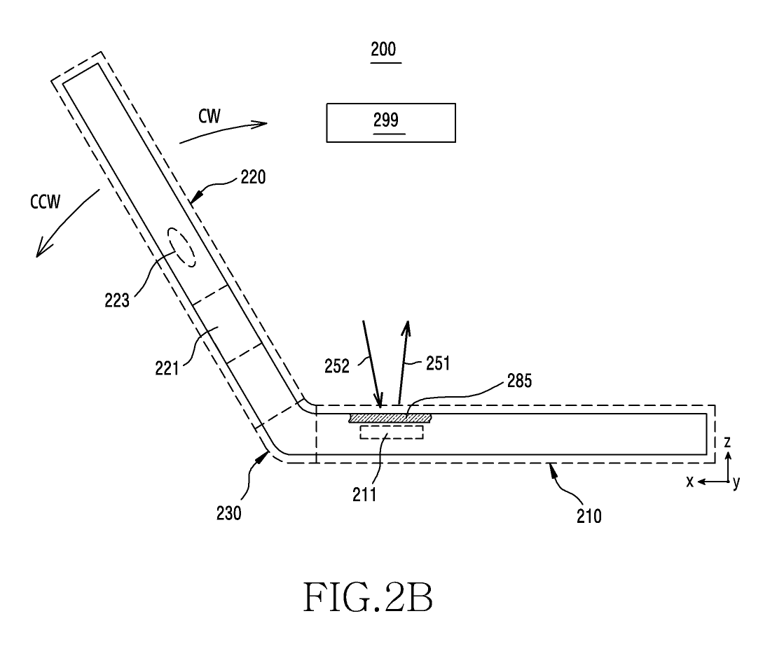

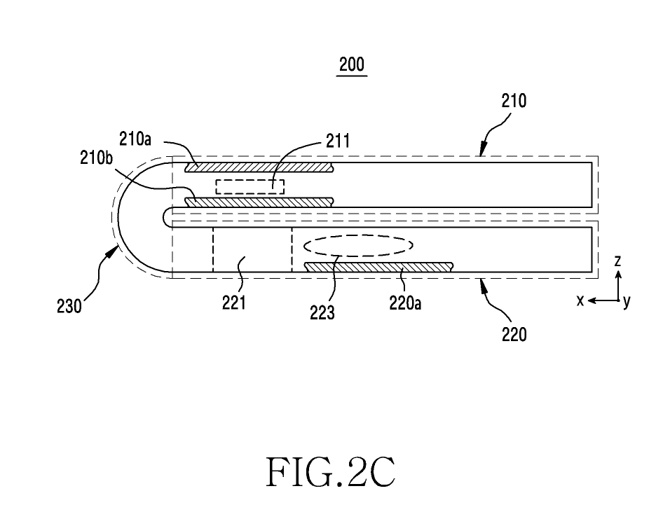

FIG. 2A illustrates a first folded state of a flexible electronic device according to an embodiment of the disclosure.

FIG. 2B illustrates an unfolded state of the flexible electronic device of FIG. 2A according to an embodiment of the disclosure.

FIG. 2C illustrates a second folded state of the flexible electronic device of FIG. 2A according to an embodiment of the disclosure.

Referring to FIG. 2A, an electronic device 200 (for example, the electronic device 101 of FIG. 1) may include a first region 210, a second region 220, and a region 230 (hereinafter, referred to as a bendable region) which can be bent between the first region 210 and the second region 220. The second region 220 may be rotated with respect to the first region 210 by the bendable region 230. The bendable region 230 may include various structures for smooth rotation of the second region 220. According to an embodiment, although not illustrated, both external surfaces 2301 and 2302 of the bendable region 230 may be designed to include a concave-convex structure along a curved part, which allows smooth rotation of the second region 220.

As illustrated in FIG. 2A, when the second region 220 moves to a position at which further rotation in a first direction (for example, CW) is difficult, the electronic device 200 may be defined to be in a first folded state. According to an embodiment, the first region 210 and the second region 220 may be substantially flat, and may be parallel to each other in the first folded state.

According to an embodiment, in the first folded state, an optical sensor 211 included in the first region 210 may be arranged in a portion 221 of the second region 220. The portion 221 of the second region 220 may be a light transmission region for by the optical sensing in the first folded state. For example, external light 252 may pass through the portion 221 (hereinafter, referred to as a light transmission region) and flow into the optical sensor 211. In another example, light 251 output from the optical sensor 211 may pass through the light transmission region 221 and may be emitted to the outside. In some embodiments, even when the second region 220 has a threshold angle (for example, about 10 degrees) larger than 0 degrees from the first region 210, the optical sensor 211 is covered with the light transmission region 221 and thus the light transmission region 221 may be used as a light path. Accordingly, the first folded state may be defined as a state in which the first region 210 and the second region 220 are at an angle equal to or smaller than the threshold angle (for example, about 10 degrees). In some embodiments, at the angle equal to or smaller than the threshold angle, the light transmission region 221 may be on a straight line 2007 perpendicularly extending from the optical sensor 211.

According to an embodiment, the second region 220 may have a width (W2) which is substantially the same as the width (W1) of the first region 210 in order to cover most of the first region 210 in the first folded state. In some embodiments, the second region 220 may have a width larger or smaller than the first region 210.

According to an embodiment, the optical sensor 211 may be disposed close to the bendable region 230, and the light transmission region 221 may be disposed at a position corresponding thereto. For example, the light transmission region 221 may be disposed at a first position spaced apart from the bendable region 230 by a first distance (D1). According to some embodiments, the light transmission region 221 may be disposed at a position spaced apart from the bendable region 230 by a distance longer than the first distance (D1).

According to an embodiment, the optical sensor 211 may include at least one of the light-emitting module and the light-receiving module. The light-emitting module may include a light-emitting device such as a light-emitting diode (LED) and the light-receiving module may include a light-receiving device such as a photodiode for converting flowing light (or light energy) into an electrical signal (or electrical energy). According to an embodiment, the light-receiving module of the optical sensor 211 may be electrically connected to an analog-digital converter (ADC) or may include an ADC, and the ADC may convert an electrical signal output from the light-receiving module of the optical sensor 211 into a digital value (or an analog-digital-converted value). According to an embodiment, the optical sensor 211 may include one module (for example, a proximity sensor or a biometric sensor (for example, a heart rate sensor or a fingerprint sensor) as a chip) including both the light-emitting module and the light-receiving module. According to another embodiment, the optical sensor 211 is an element including only the light-receiving module, and may include, for example, an illumination sensor.

The light-receiving module of the optical sensor 211 may include at least one light-receiving region for receiving light of at least one wavelength band. For example, the light-receiving module may include a first light-receiving region for receiving light of a first wavelength band and a second light-receiving region for receiving light of a second wavelength band. However, the disclosure is not limited thereto and may further include more light-receiving regions for receiving light of the corresponding wavelength band. The first wavelength band and the second wavelength band may be different or may partially overlap each other. According to an embodiment, the first light-receiving region may receive light of a maximum sensitivity wavelength in the first wavelength band, and the second light-receiving region may receive light of a maximum sensitivity wavelength in the second wavelength band. The first light-receiving region and the second light-receiving region may be separated from each other, and, for example, the first light-receiving region may be surrounded by the second light-receiving region.

According to an embodiment, the processor (for example, the processor 120 of FIG. 1) of the electronic device 200 may selectively activate one of a plurality of light-receiving regions of the light-receiving module on the basis of the sensing mode. For example, the sensing mode may include various modes, such as a mode for sensing the proximity of an external object (or entity) through light of a corresponding wavelength (for example, about 940 nm or about 950 nm), a mode for sensing biometric information (for example, a fingerprint, iris, or skin state (skin moisture, skin melanin, or skin red spots)) using light of the corresponding wavelength, or a mode for sensing an external environment such as illumination through light of a corresponding wavelength. According to an embodiment, the processor of the electronic device 200 may select at least one of the plurality of sensing modes at least on the basis of user input and/or an executed application and selectively activate at least one of the plurality of light-receiving regions corresponding to the at least one selected sensing mode. For example, when a call application is executed, the processor of the electronic device 200 may select a mode (hereinafter, referred to as a proximity-sensing mode) for sensing proximity of the external object and selectively activate at least one light-receiving region corresponding to the proximity-sensing mode. In the proximity-sensing mode, when an object (for example, a user face) moves close (10 cm or closer) to the light transmission region 221 of the electronic device 200 in the first folded state, light of the wavelength band for proximity sensing which is output from the light-emitting module of the optical sensor 211 may pass through the light transmission region 221 and may be scattered or reflected. The scattered or reflected light of the wavelength band for proximity sensing may pass through the light transmission region 221 and flow into the light-receiving module of the optical sensor 211, and the light-receiving module may generate an electrical signal indicating whether the object is close or the distance of the object on the basis of the flowing scattered or reflected light. As the distance between the light transmission region 221 and the external object is shorter, the amount of light that is scattered or reflected from the external object and flows into the light-receiving module of the optical sensor 211 increases and a sensing value according thereto may be changed. In the proximity-sensing mode, the processor of the electronic device 200 may determine the distance between the electronic device 200 and the external object on the basis of the sensing value.

The light-emitting module of the optical sensor 211 may include at least one light source which can generate light of one or more wavelength bands. According to an embodiment, the light-emitting module of the optical sensor 211 may generate light of a broad wavelength band as a single light source.

According to various embodiments, the light-emitting module of the optical sensor 211 may be designed to selectively generate light of the corresponding wavelength band under the control of the processor (for example, the processor 120 of FIG. 1). For example, in the proximity-sensing mode, the processor 120 may control the light-emitting module of the optical sensor 211 to generate light of the wavelength band for proximity sensing.

According to some embodiments, the light-emitting module of the optical sensor 211 may include a plurality of light sources, and the plurality of light sources may generate light of one or more wavelength bands. For example, in the proximity-sensing mode, the processor (for example, the processor 120 of FIG. 1) may select and activate at least one light source for generating light of the wavelength band for proximity sensing among the plurality of light sources of the light-emitting module of the optical sensor 211.

According to some embodiments, the light-emitting module of the optical sensor 211 may be some pixels of the display (for example, the display device 160 of FIG. 1) included in the electronic device 200. In the corresponding sensing mode, the processor (for example, the processor 120 of FIG. 1) may perform control to output light of the corresponding wavelength band through configured pixels of the display.

According to an embodiment, the light transmission region 221 may be one region corresponding both to the light-receiving module and to the light-emitting module of the optical sensor 211. According to some embodiments, the light transmission region 221 may be designed to have a structure in which a region for the light-receiving module of the optical sensor 211 and a region for the light-emitting module of the optical sensor 211 are separated from each other.

According to various embodiments, the optical sensor 211 (or hereinafter, referred to as a second optical sensor 223 described below) may be defined as a multi-functional optical sensor for supporting various sensing modes. The multi-functional optical sensor may receive light of one or more wavelength bands, such as visible light, infrared light, or ultraviolet light, and may identify the intensity of light or the type thereof.

According to various embodiments, the optical sensor 211 may include an image sensor such as a camera included in an iris scanner or a color sensor such as a red, green, blue (RGB) sensor. According to various embodiments, the optical sensor 211 may include a photoplethysmogram (PPG)-based biometric sensor. According to various embodiments, the optical sensor 211 may include a three-dimensional (3D) detection sensor and may be used to determine a depth using infrared radiation.

The light transmission region 221 may be designed such that light 251 output from the optical sensor 211 or external light 252 is not attenuated while passing through the light transmission region 221 in consideration of the characteristics of light passing through a medium (straightness, reflection, penetration, refraction, and scattering). For example, the light transmission region 221 may be designed in various media or forms to have a low optical absorption rate, a high light penetration ratio (for example, a straight penetration ratio or a diffusion penetration ratio), or low reflectivity. When the light transmission region 221 is designed to reduce the attenuation of light, the luminous intensity when the light 251 output from the optical sensor 211 is emitted to the outside or the luminous intensity when the external light 252 flows into the optical sensor 211 may increase. Accordingly, the light transmission region 221 may reduce the deterioration of light-sensing performance by the optical sensor 211.

According to an embodiment, the cross section of the light transmission region 221 may be a rectangle including a width in an x direction and a thickness in a z direction. The width (W3) of the light transmission region 221 may extend to cover the optical sensor 211, and may have various shapes such as a circle and a rectangle when viewed from the top of the second region 220 in the first folded state.

According to an embodiment, both external surfaces 2211a and 2212a of the light transmission region 221 may be designed to have surface flatness or surface roughness which is 0 or close to 0, which may reduce the diffuse reflection or diffuse refraction of light by the surface, thereby decreasing attenuation by the light transmission region 221. For example, an average roughness value (Ra) or a maximum roughness value (Rmax) of the central line of both external surfaces 2211a and 2212a of the light transmission region 221 may be equal to or smaller than 5 μm.

One external surface 2211a of the light transmission region 221 and an adjacent external surface 2211c may be smoothly connected, and the other external surface 2212a of the light transmission region 221 and an adjacent external surface 2212c may be smoothly connected. According to an embodiment, the second region 220 may include an actually transparent third plate 220a and fourth plate 220b. The third plate 220a may form external surfaces 2211a and 2211c on one side of the second region 220 (hereinafter, referred to as a third surface) and the fourth plate 220b may form external surfaces 2212a and 2212c on the other side of the second region 220 (hereinafter, referred to as a fourth surface). According to an embodiment, the third plate 220a or the fourth plate 220b may include a glass plate or a polymer plate. According to some embodiments, the third plate 220a or the fourth plate 220b may be a plate including various coating layers.

The light transmission region 221 may include a plurality of medium layers. According to an embodiment, although not illustrated, the light transmission region 221 may include a first medium layer, which is a portion of the third plate 220a, a second medium layer, which is a portion of the fourth plate 220b, and a third medium layer, including a space disposed between the first medium layer and the second medium layer. The third medium layer may correspond to an opening formed in an actually opaque support member 222 disposed between the third plate 220a and the fourth plate 220b, and may include air. The external light 252 may pass through a plurality of medium layers (for example, the first medium layer, the second medium layer, and the third medium layer) of the light transmission region 221 and flow into the optical sensor 211. The light 251 output from the optical sensor 211 may pass through the plurality of medium layers of the light transmission region 221 and may be emitted to the outside.

According to an embodiment, an internal surface of the first medium layer (for example, an opposite surface of the external surface 2211a) or an internal surface of the second medium layer (for example, an opposite surface of the external surface 2212a) may be designed to have surface flatness or surface roughness which is 0 or close to 0, which may reduce diffuse reflection or diffuse refraction by the surface and thus decrease attenuation by the light transmission region 221. For example, an average roughness value (Ra) or a Rmax of the central line of the internal surface of the first medium layer or the second medium layer may be equal to or smaller than 5 μm.

According to some embodiments, the light transmission region 221 may be designed in a form in which the first medium layer of the third plate 220a or the second medium layer of the fourth plate 220b are removed.

According to various embodiments, the first medium layer or the second medium layer may be designed to include a filter such that the third medium layer, which is an empty space, is not visible. For example, the first medium layer or the second medium layer may include various filters for reducing light reflected from the light transmission region 221.

According to some embodiments, the first medium layer or the second medium layer may include a filter through which light of a light wavelength band used by the optical sensor 211 selectively passes.

According to various embodiments, the light transmission region 221 may be designed to reduce reflection of the light 251 output from the optical sensor 211 or the external light 252.

According to an embodiment, the light transmission region 221 may include a lens module 270. The lens module 270 may be disposed between the first medium layer and the second medium layer and allow the light 251 output from the optical sensor 211 to pass through the light transmission region 221 and be emitted to the outside. The lens module 270 may be provided in various forms to improve the straightness of light or to indicate or change the direction of light.

According to various embodiments, the lens module 270 may be designed to be combined with the fourth plate 220b or to be included in the fourth plate 220b. For example, the second medium layer may be designed to have the function of the lens module.

According to various embodiments, the lens module 270 may be designed to be combined with the third plate 220a or to be included in the third plate 220a. For example, the first medium layer may be designed to have the function of the lens module.

According to some embodiments, the lens module 270 may be designed to be disposed between the first region 210 and the second region 220 in the first folded state.

According to some embodiments, the lens module 270 may be omitted.

Referring back to FIG. 2A, according to an embodiment, a gap (hereinafter, referred to as a fourth medium layer) including air may exist between the optical sensor 211 and the light transmission region 221 in the first folded state. The light 251 output from the optical sensor 211 may pass through the fourth medium layer and reach the light transmission region 221. The external light 252, having passed through the light transmission region 221, may pass through the fourth medium layer and reach the optical sensor 211. According to some embodiments, the gap between the optical sensor 211 and the light transmission region 221 may be designed to be 0 or close to 0 in the first folded state.

According to an embodiment, the first region 210 may include a first surface 2001 facing the third surface 2211a and 2211c of the second region 220 and a second surface 2002 opposite the first surface in the first folded state. According to an embodiment, the first region 210 may include a first plate 210a forming the first surface 2001 and a second plate 210b forming the second surface 2002. The optical sensor 211 may be covered by the first plate 210a. In the first folded state, a portion of the first plate 210a covering the optical sensor 211 may be a fifth medium layer through which the light 251 or 252 passes.

According to an embodiment, the first region 210 may include a first display 291 (for example, the display device 160 of FIG. 1) disposed between the first plate 210a and the second plate 210b, and may be coupled to the first plate 210a. In the first folded state 200a, the processor (for example, the processor 120 of FIG. 1) of the electronic device 200 may be designed to deactivate the first display 291. According to an embodiment, the light-emitting module of the optical sensor 211 may be disposed to be adjacent to the first display 291. For example, the light-emitting module of the optical sensor 211 may be disposed on a space 2911 next to the first display 291. According to an embodiment, the light-receiving module of the optical sensor 211 may be disposed to be adjacent to the first display 291. For example, the light-receiving module of the optical sensor 211 may be disposed on the space 2911 next to the first display 291 or below the rear surface 2912 of the first display 291.

According to an embodiment, the first region 210 may include a support member 271 disposed between the first display 291 and the second plate 210b. The support member 271 is a part to which the electronic elements included in the first region 210 are coupled, and may be designed to be rigid in order to provide durability or hardness to the first region 210. For example, the first display 291 may be coupled to one side of the support member 271, and may be disposed between the first plate 210a and the support member 271. A printed circuit board (not shown) may be coupled to the other side of the support member 271, and may be disposed between the support member 271 and the second plate 210b. According to various embodiments, the support member 271 may include a part (for example, a lateral bezel structure) (not shown) surrounding the space between the first plate 210a and the second plate 210b and forming the lateral side of the first region 210. According to an embodiment, the optical sensor 211 may be coupled to the support member 271 and electrically connected to the printed circuit board through a flexible printed circuit board (FPCB). According to another embodiment, the optical sensor 211 may be mounted to the printed circuit board.

According to various embodiments, the first region 210 may be designed to be flexible, and the first plate 210a, the second plate 210b, the first display 291, or the support member 271 included therein may be formed to support the first area. For example, the printed circuit board may also be designed to be flexible, or may be disposed in a region (for example, the region 2911) of the first region 210 which is bent less. According to some embodiments, when the first plate 210a is designed to have a back plane serving as the support member 271, at least a part of the support member 271 may be omitted.

According to various embodiments, the second region 220 may include a second display 292 (for example, the display device 160 of FIG. 1) disposed between the third plate 220a and the fourth plate 220b. The second display 292 may be coupled to the fourth plate 220b and the support member 222. According to various embodiments, the second region 220 may be designed to be flexible, and the third plate 220a, the fourth plate 220b, the support member 222, or the second display 292 included therein are formed to support the second region. According to an embodiment, when it is required to display an image in the unfolded state 200b, the processor (for example, the processor 120 of FIG. 1) of the electronic device 200 may be designed to selectively activate the second display 292, among the first display 291 and the second display 292. Light related to the image output from the second display 292 may be emitted to the outside through the fourth plate 220b.

According to various embodiments, the second region 220 may include a third display 293 (for example, the display device 160 of FIG. 1) disposed between the third plate 220a and the fourth plate 220b. A third display 293 may be coupled to the third plate 220a and the support member 222. When it is required to display an image in the first folded state, the processor (for example, the processor 120 of FIG. 1) of the electronic device 200 may be designed to selectively activate the second display 292, among the first display 291, the second display 292, and the third display 293.

According to an embodiment, the second display 292 may be electrically connected to the printed circuit board of the first region 210 and may be controlled by the processor (for example, the processor 120 of FIG. 1) mounted on the printed circuit board. In this case, the bendable region 230 may be designed to include an element such as an FPCB electrically connecting the first region 210 and the second region 220.

According to some embodiments, the electronic device 200 may be designed to include an integrated flexible display formed along the first surface 2001 of the first region 210, the third surface 2003 of the second region 220, and the surface 2301 of the bendable region 230 instead of the first display 291 and the third display 293. According to various embodiments, the electronic device 200 may be designed to include an integrated flexible plate formed along the first surface 2001 of the first region 210, the third surface 2003 of the second region 220, and the surface 2301 of the bendable region 230 instead of the first plate 210a and the third plate 220a. According to an embodiment, the integrated flexible plate may be formed of various polymer materials such as polyimide. According to various embodiments, in the first folded state, the processor (for example, the processor 120 of FIG. 1) may be designed to deactivate the integrated flexible display.

According to various embodiments, the second region 220 may further include an optical sensor 223 (hereinafter, referred to as a second optical sensor) including at least one of the light-emitting module and the light-receiving module. The second optical sensor 223 may be designed in a structure which is at least partially similar to or is the same as the optical sensor 211 (hereinafter, referred to as a first optical sensor) of the first region 210. According to an embodiment, the processor (for example, the processor 120 of FIG. 1) may execute the corresponding sensing mode by selecting using the light-emitting module of the second optical sensor 223 and the light-receiving module of the first optical sensor 211 in the first folded state. For example, when the proximity-sensing mode is executed in the first folded state, light output from the light-emitting module of the second optical sensor 223 may pass through the fourth plate 220b and be emitted to the outside, and the emitted light may be reflected or scattered from the external object 299. The light reflected or scattered from the external object 299 may pass through the light transmission region 221 and flow into the light-receiving module of the first optical sensor 211.

According to another embodiment, the processor (for example, the processor 120 of FIG. 1) may execute the corresponding sensing mode by selectively using the light-emitting module of the first optical sensor 211 and the light-receiving module of the second optical sensor 223 in the first folded state. For example, when the proximity-sensing mode is executed in the first folded state, the light 251 output from the light-emitting module of the first optical sensor 211 may pass through the light transmission region 221 and be emitted to the outside, and the emitted light may be reflected or scattered from the external object 299. The light reflected or scattered from the external object 299 may pass through the fourth plate 220b and flow into the light-receiving module of the second optical sensor 223. In this case, the light-receiving module of the second optical sensor 223 may be disposed below the rear surface 2922 of the second display 292, or may be disposed in the space 2921 next to the second display 292.

In the first folded state, the light 251 or 252 may pass through the first medium layer, the second medium layer, the third medium layer, the fourth medium layer, and the fifth medium layer. A portion of the light 251 output from the first optical sensor 211 may be reflected from a boundary surface between medium layers having different refractive indices, and may have difficulty in being emitted to the outside. A portion of the external light 252 may be reflected from a boundary surface between the medium layers having different refractive indices and may have difficulty in flowing into the first optical sensor 211. According to an embodiment, the lens module 270 may serve to reduce attenuation of the light 251 or 252. According to various embodiments, the lens module 270 may be designed to be coupled to the first plate 210a or included in the first plate 210a, which may further reduce attenuation of the light 251 output from the first optical sensor 211. According to some embodiments, the lens module 270 may be disposed between the first plate 210a and the first optical sensor 211.

According to some embodiments, the electronic device 200 may omit at least one of the elements, or may add one or more other elements.

Referring to FIG. 2B, when the second region 220 can rotate in a first direction (for example, a CW direction) or a second direction (for example, a CCW direction), the electronic device 200 may be defined to be in the unfolded state. The processor (for example, the processor 120 of FIG. 1) may execute the corresponding sensing mode by using the light-emitting module or the light-receiving module of at least one of the first optical sensor 211 and the second optical sensor 223 in the unfolded state.

In the unfolded state, the first optical sensor 211 may be in the state in which the first optical sensor is not covered by the light transmission region 221. In the unfolded state, the light 251 output from the first optical sensor 211 may pass through the fifth medium layer 285 and be emitted to the outside. In the unfolded state, the external light 252 may pass through the fifth medium layer 285 and flow into the first optical sensor 211. In the unfolded state, the number of medium layers through which the light 251 or 252 passes is smaller than in the folded state of FIG. 2A, and thus the attenuation of the light 251 or 252 may be relatively lower.

Referring to FIGS. 2A and 2B, when the light-emitting module of the first optical sensor 211 is driven with substantially constant light output power, the intensity of the light 252 output from the light source of the first optical sensor 211 in the unfolded state and the intensity of the light 252 output from the light source of the first optical sensor 211 in the first folded state may be constant. In the unfolded state, the light 252 output from the light-emitting module of the first optical sensor 211 may pass through the fifth medium layer and reach the external object 299. In the first folded state, the light 252 output from the light-emitting module of the first optical sensor 211 may pass through a larger number of medium layers, compared to the unfolded state, and reach the external object 299. The light 251 reflected or scattered from the external object 299 may also pass through a larger number of medium layers in the first folded state, compared to the unfolded state, and reach the first optical sensor 211. Accordingly, in the first folded state, the light 251 or 252 may be further attenuated compared to the unfolded state. As described above, when the light-emitting module of the first optical sensor 211 is driven with constant light output power in the unfolded state and in the folded state, a sensing value output from the light-receiving module of the first optical sensor 211 in the unfolded state and a sensing value output from the light-receiving module of the first optical sensor 211 in the first folded state may be different from each other even through the external object 299 has the same separation distance. Accordingly, although the external object 299 has the same separation distance, there may be an error in that the proximity distance recognized in the unfolded state and the proximity distance recognized in the first folded state do not match.

According to an embodiment, the processor (for example, the processor 120 of FIG. 1) may control light output power (or power, current, or voltage) of the light-emitting module included in the first optical sensor 211 on the basis of the unfolded state or the first folded state. For example, the processor 120 may enable the light-emitting module of the first optical sensor 211 to be driven with first light output power in the unfolded state and the light-emitting module of the first optical sensor 211 to be driven with second light output power, which is larger than the first light output power, in the first folded state. Accordingly, the amount of light (or an intensity of light) emitted to the outside in the unfolded state and the amount of light emitted to the outside in the first folded state may be substantially constant. When the amount of light reaching the external object 299 in the unfolded state and the amount of light reaching the external object 299 in the first folded state are substantially constant, the error may be reduced.

Referring to FIGS. 2A and 2B, according to an embodiment, the processor (for example, the processor 120 of FIG. 1) may determine the proximity of the external object on the basis of a proximity recognition threshold value, which is a reference for determining proximity recognition, and a proximity release threshold value, which is a reference for determining proximity release. Light of a wavelength band for proximity sensing, which is scattered or reflected from the external object 299, may flow into the light-receiving module of the first optical sensor 211. The light-receiving module of the first optical sensor 211 may generate a digital value (hereinafter, referred to as a sensing value) proportional to the amount of light flowing thereto. According to an embodiment, an operation flow for determining the proximity of the external object may include a proximity recognition operation flow for determining whether the external object 299, which is outside a proximity recognition range (for example, about 10 cm), moves within the proximity recognition range from the first optical sensor 211.

According to an embodiment, in the proximity recognition operation flow, the processor (for example, the processor 120 of FIG. 1) may select or control the proximity recognition threshold value on the basis of the unfolded state or the first folded state. The processor 120 may compare the selected proximity recognition threshold value with the sensing value generated by the first optical sensor 211. When the sensing value generated by the first optical sensor 211 is larger than or equal to the selected proximity recognition threshold value, the processor 120 may determine that the external object 299 is located within the proximity recognition range. As described above, when the light-emitting module of the first optical sensor 211 is driven with fixed light output power in the unfolded state and the first folded state, the amount of light reaching the external object 299 in the unfolded state and the amount of light reaching the external object 299 in the first folded state may be different due to the difference between medium layers in the unfolded state and medium layers in the first folded state. When the light-emitting module of the first optical sensor 211 is driven with fixed output power in the unfolded state and the first folded state, if a proximity recognition threshold value used in the unfolded state and a proximity recognition threshold value used in the first folded state are configured as difference values, the error may be reduced.

According to an embodiment, the operation flow for determining the proximity of the external object may further include a proximity release operation flow for determining whether the external object 299, which is within a proximity release range, moves to the outside of the proximity release range from the first optical sensor 211. The proximity release range may be designed to be wider than the proximity recognition range.

According to an embodiment, in the proximity release operation flow, the processor (for example, the processor 120 of FIG. 1) may select or control the proximity release threshold value on the basis of the unfolded state or the first folded state. The processor 120 may compare the selected proximity release threshold value with the sensing value generated by the first optical sensor 211. When the sensing value generated by the first optical sensor 211 is smaller than the selected proximity release threshold value, the processor (for example, the processor 120 of FIG. 1) may determine that the external object 299 has moved to the outside of the proximity release range. According to an embodiment, the proximity release threshold value may be designed to be smaller than the proximity recognition threshold value. As described above, when the light-emitting module of the first optical sensor 211 is driven with fixed light output power in the unfolded state and the first folded state, the amount of light reaching the external object 299 in the unfolded state and the amount of light reaching the external object 299 in the first folded state may be different due to the difference between medium layers in the unfolded state and medium layers in the first folded state. When the light-emitting module of the first optical sensor 211 is driven with fixed output power in the unfolded state and the first folded state, if the proximity release threshold value used in the unfolded state and the proximity release threshold value used in the first folded state are configured as different values, the error may be reduced.

Referring to FIG. 2C, when the second region 220 moves to a position at which further rotation in the second direction (for example, a CCW direction) is difficult, the electronic device 200 may be defined to be in a second folded state. The processor (for example, the processor 120 of FIG. 1) may execute the corresponding sensing mode by using the light-emitting module or the light-receiving module of at least one of the first optical sensor 211 and the second optical sensor 223 in the second folded state. According to an embodiment, in the second folded state, light output from the light-emitting module of the first optical sensor 211 may pass through the first plate 210a and be emitted to the outside, and external light may pass through the first plate 210a and flow into the first optical sensor 211. According to another embodiment, in the second folded state, light output from the light-emitting module of the second optical sensor 223 may pass through the third plate 220a and be emitted to the outside, and external light may pass through the third plate 220a and flow into the second optical sensor 223.

According to some embodiments, in the second folded state, light output from the first optical sensor 211 may pass through the second plate 210b and the light transmission region 221 and be emitted to the outside, or external light may pass through the light transmission region 221 and the second plate 210b and flow into the first optical sensor 211. According to an embodiment, in the second folded state, the processor 120 may execute the corresponding sensing mode for selectively using the light-emitting module and the light-receiving module of the first optical sensor 211, among the first optical sensor 211 and the second optical sensor 223. For example, in the proximity-sensing mode, light output from the first optical sensor 211 may pass through the light transmission region 221 and be emitted to the outside, and light reflected or scattered from the external object may pass through the light transmission region 221 and flow into the first optical sensor 211.

According to another embodiment, in the second folded state, the processor (for example, the processor 120 of FIG. 1) may execute the corresponding sensing mode for selectively using the light-emitting module of the first optical sensor 211 and the light-receiving transmission region 221. For example, in the proximity-sensing mode, light output from the first optical sensor 211 may pass through the light transmission region 221 and be emitted to the outside and light reflected or scattered from the external object may pass through the light transmission region 221 and flow into the first optical sensor 211.

According to another embodiment, in the second folded state, the processor (for example, the processor 120 of FIG. 1) may execute the corresponding sensing mode for selectively using the light-receiving module of the first optical sensor 211 and the light-emitting module of the second optical sensor 223. For example, in the proximity-sensing mode, light output from the second optical sensor 223 may pass through the third plate 220a and be emitted to the outside, and light reflected or scattered from the external object may pass through the light transmission region 3 and flow into the first optical sensor 211.

According to various embodiments, operation flow for controlling light output power of a light source when a fixed proximity recognition threshold value and/or a proximity release threshold value are used may be variously designed when at least one of the light-receiving module and/or the light-emitting module for the corresponding sensing mode is selectively used in the first folded state of FIG. 2A, the unfolded state of FIG. 2B, or the second folded state of FIG. 2C.

According to various embodiments, an operation flow for controlling a proximity recognition threshold value and/or a proximity release threshold value when a light source is driven with fixed light output power may be variously designed when at least one of the light-receiving module and/or the light-emitting module for the corresponding sensing mode is selectively used in the first folded state of FIG. 2A, the unfolded state of FIG. 2B, or the second folded state of FIG. 2C.

According to some embodiments, when at least one of the light-receiving module and/or the light-emitting module for the corresponding sensing mode is selectively used in the first folded state of FIG. 2A, the unfolded state of FIG. 2B, or the second folded state of FIG. 2C, both the operation flow for controlling light output power of the light-emitting module and the operation flow for controlling the proximity recognition threshold value and/or the proximity release threshold value may be used.

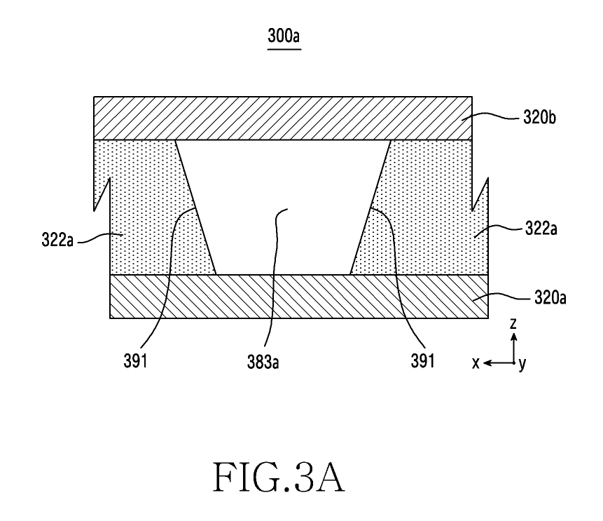

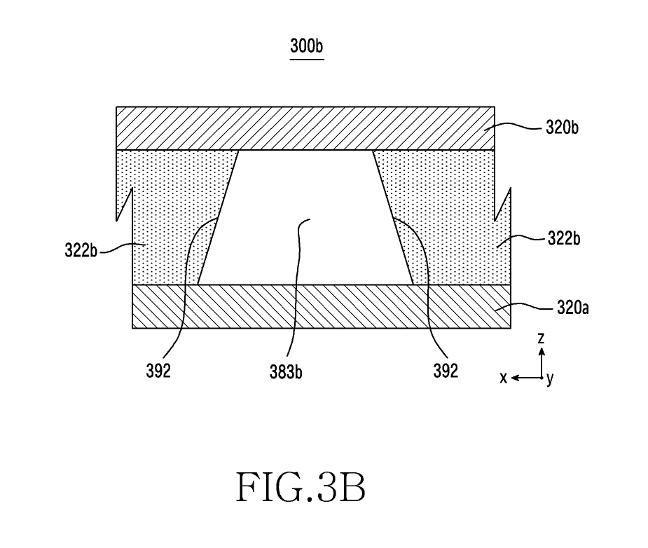

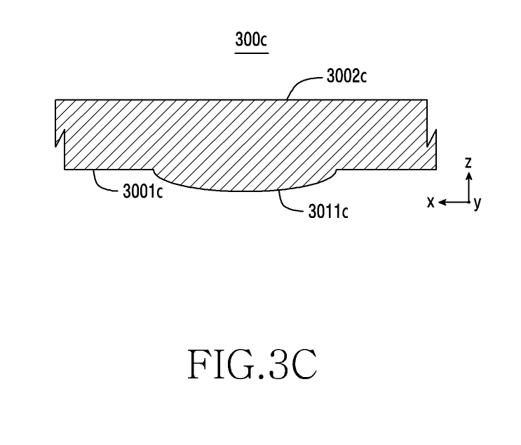

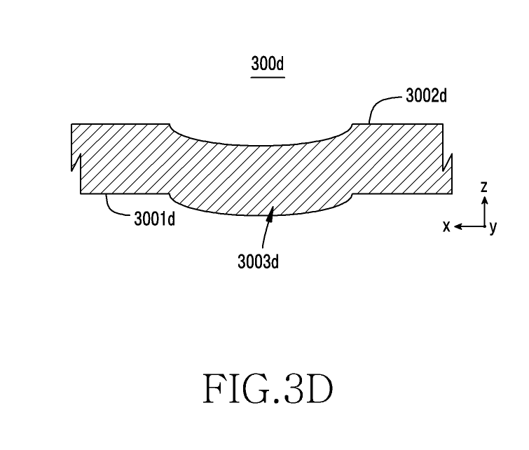

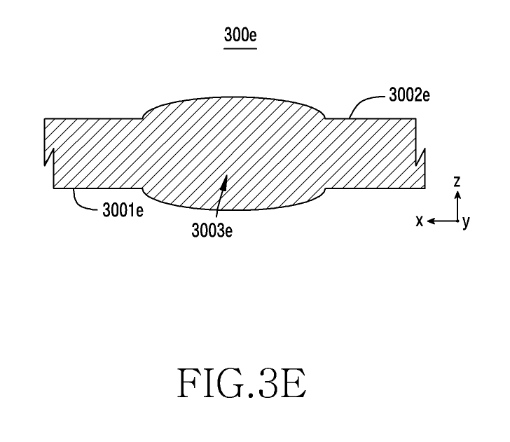

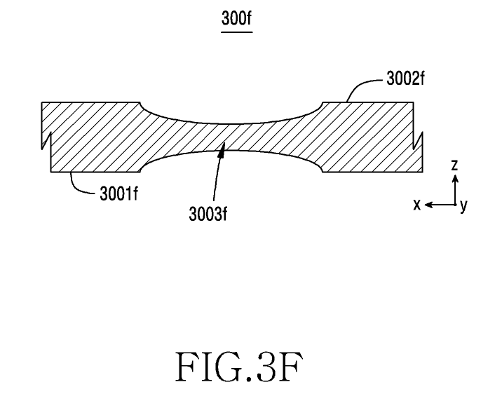

FIGS. 3A and 3B are cross-sectional views of a light transmission region according to various embodiments of the disclosure.

FIGS. 3C, 3D, 3E, and 3F are cross-sectional views of a plate included in a light transmission region according to various embodiments of the disclosure.

Referring to FIG. 3A, a support member 322a may be disposed between a third plate 320a (for example, the third plate 220a of FIG. 2A) and a fourth plate 320b (for example, the fourth plate 220b of FIG. 2A), and may include a through space 383a (for example, the third medium layer in FIG. 2). According to an embodiment, the support member 322a may be replaced with the support member 222 of FIG. 2A, and the through space 383a may be a medium layer through which light passes. According to an embodiment, a boundary surface 391 between the support member 322a and the through space 383a may be inclined in a direction from the third plate 320a to the fourth plate 320b, and the through space 383a may become wider in that direction. When the structure 300a of FIG. 3A is applied to FIG. 2A, the external light 252 may smoothly flow in the optical sensor 211 or the light 251 output from the optical sensor 211 may be smoothly emitted to the outside in the first folded state (see FIG. 2A).

Referring to FIG. 3B, the support member 322b may be disposed between the third plate 320a (for example, the third plate 220a of FIG. 2A) and the fourth plate 320b (for example, the fourth plate 220b of FIG. 2A) and may include a through space 383b (for example, the third medium layer of FIG. 2). According to an embodiment, the support member 322b of FIG. 3B may be replaced with the support member 222 of FIG. 2A, and the through space 383b may be a medium layer through which light passes. According to an embodiment, a boundary surface 392 between the support member 322b and the through space 383b may be inclined in a direction from the third plate 320a to the fourth plate 320b, and the through space 383a may become narrower in that direction. When the structure 300b of FIG. 3B is applied to FIG. 2A, the external light 252 may smoothly flow in the optical sensor 211, or the light 251 output from the optical sensor 211 may be smoothly emitted to the outside in the first folded state (see FIG. 2A).

Referring to FIG. 3C, the plate 300c may include both surfaces 3001c and 3002c disposed on opposite sides, and may include a convexly protruding part 3011c on one surface 3002c, among both surfaces 3001c and 3002c, according to an embodiment. According to an embodiment, the plate 3001c of FIG. 3C may be replaced with the third plate 220a or the fourth plate 220b of FIG. 2A, and the convex part 3011c may be arranged in the light transmission region 221. For example, the plate 300c of FIG. 3C may be replaced with the fourth plate 220b of FIG. 2A, and the convex part 3011c may be disposed toward the third plate 220a, or may be inversely disposed to form the portion 2212a of the fourth surface (the surfaces 2212a and 2212c of FIG. 2A). In another example, the plate 300c of FIG. 3C may be replaced with the third plate 220a of FIG. 2A, and the convex part 3011c may be disposed toward the fourth plate 220b, or may be inversely disposed to form the portion 2211a of the third surface (the surfaces 2211a and 2211c of FIG. 2A). The plate 300c of FIG. 3C may provide a function similar to the lens module 270 of FIG. 2A, and the lens module 270 of FIG. 2A may be omitted according to some embodiments.

Referring to FIG. 3D, the plate 300d may include both surfaces 3001d and 3002d disposed on opposite sides, and may include a curved part 3003d which is concavely recessed into one surface 3002d and convexly protruding from the other surface 3001d according to an embodiment. According to an embodiment, the plate 300d of FIG. 3D may be replaced with the third plate 220a or the fourth plate 220b of FIG. 2A, and the curved part 3003d may be arranged in the light transmission region 221. For example, the plate 300d of FIG. 3D may be replaced with the fourth plate 220b of FIG. 2A, and the curved part 3003d may be disposed toward the third plate 220a, or may be inversely disposed to form the portion 2212a of the fourth surface (the surfaces 2212a and 2212c of FIG. 2A). In another example, the plate 300d of FIG. 3D may be replaced with the third plate 220a of FIG. 2A, and the curved part 3003d may be disposed toward the fourth plate 220b, or may be inversely disposed to form the portion 2211a of the third surface (the surfaces 2211a and 2212c of FIG. 2A). The plate 300d of FIG. 3D may provide a function similar to the lens module 270 of FIG. 2A, and the lens module 270 of FIG. 2A may be omitted according to some embodiments.

Referring to FIG. 3E, the plate 300e may include both surfaces 3001e and 3002e disposed on opposite sides, and may include a convex part 3003e which convexly protrudes from both surfaces 3001e and 3002e according to an embodiment. According to an embodiment, the plate 300e of FIG. 3E may be replaced with the third plate 220a or the fourth plate 220b of FIG. 2A, and the convex part 3003e may be arranged in the light transmission region 221. For example, the plate 300e of FIG. 3E may be replaced with the fourth plate 220b of FIG. 2A, and the convex part 3003e may be disposed toward the third plate 220a, or may be inversely disposed to form the portion 2212a of the fourth surface (the surfaces 2212a and 2212c of FIG. 2A). In another example, the plate 300e of FIG. 3E may be replaced with the third plate 220a of FIG. 2A, and the convex part 3003e may be disposed toward the fourth plate 220b, or may be inversely disposed to form the portion 2211a of the third surface (the surfaces 2211a and 2211c of FIG. 2A). The plate 300e of FIG. 3E may provide a function similar to the lens module 270 of FIG. 2A, and the lens module 270 of FIG. 2A may be omitted according to some embodiments.

Referring to FIG. 3F, the plate 300f may include both surfaces 3001f and 3002f disposed on opposite sides, and may include a concave part 3003f which is concavely recessed for both surfaces 3001f and 3002f according to an embodiment. According to an embodiment, the plate 300f of FIG. 3F may be replaced with the third plate 220a or the fourth plate 220b of FIG. 2A, and the concave part 3003f may be arranged in the light transmission region 221. For example, the plate 300f of FIG. 3F may be replaced with the fourth plate 220b of FIG. 2A, and the concave part 3303f may be disposed toward the third plate 220a, or may be inversely disposed to form the portion of the fourth plate 2004. In another example, the plate 300f of FIG. 3F may be replaced with the third plate 220a of FIG. 2A, and the concave part 3303f may be disposed toward the fourth plate 220b, or may be inversely disposed to form the portion of the third surface 2003. The plate 3003f of FIG. 3F may provide a function similar to the lens module 270 of FIG. 2A, and the lens module 270 of FIG. 2 may be omitted according to some embodiments.

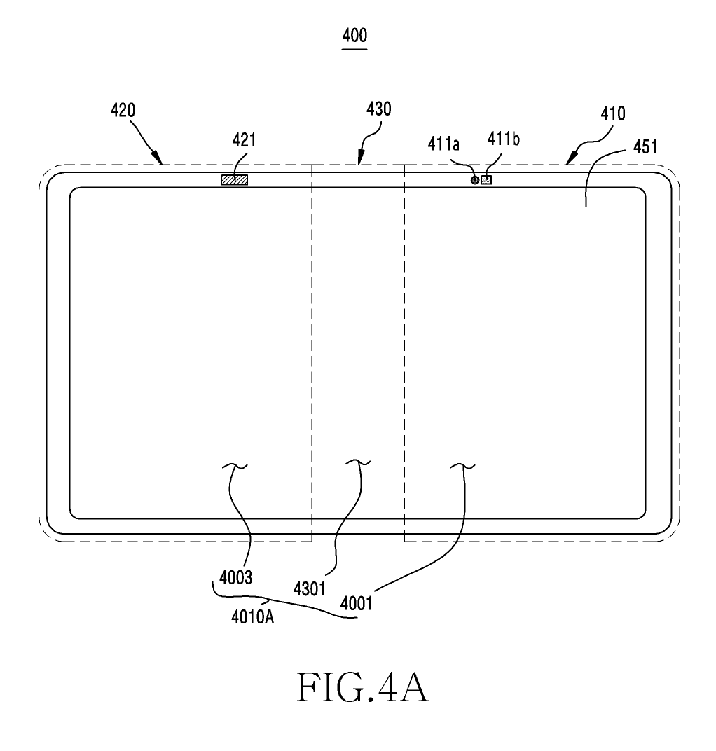

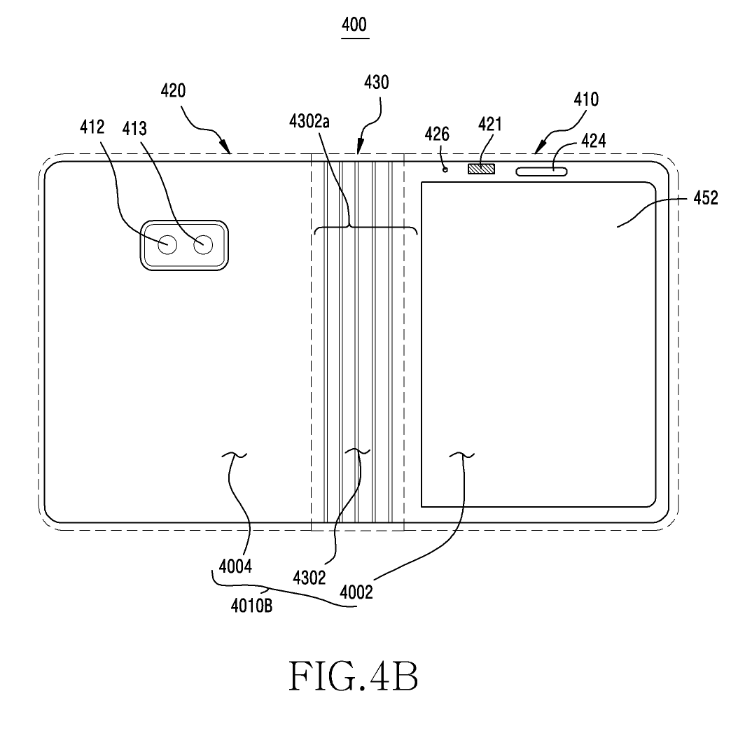

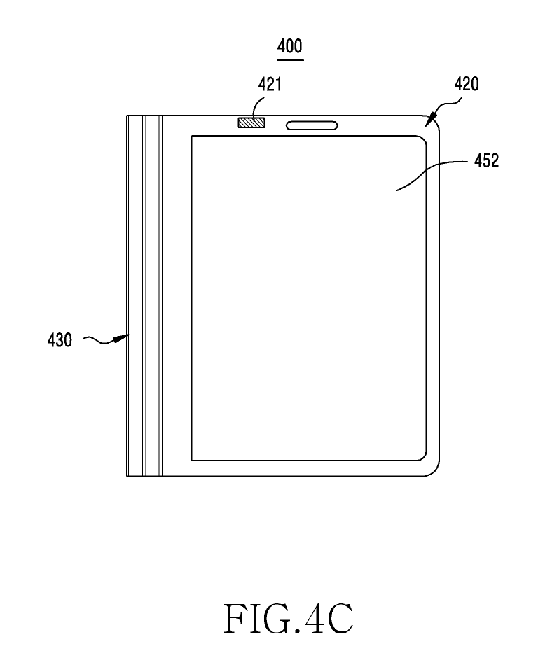

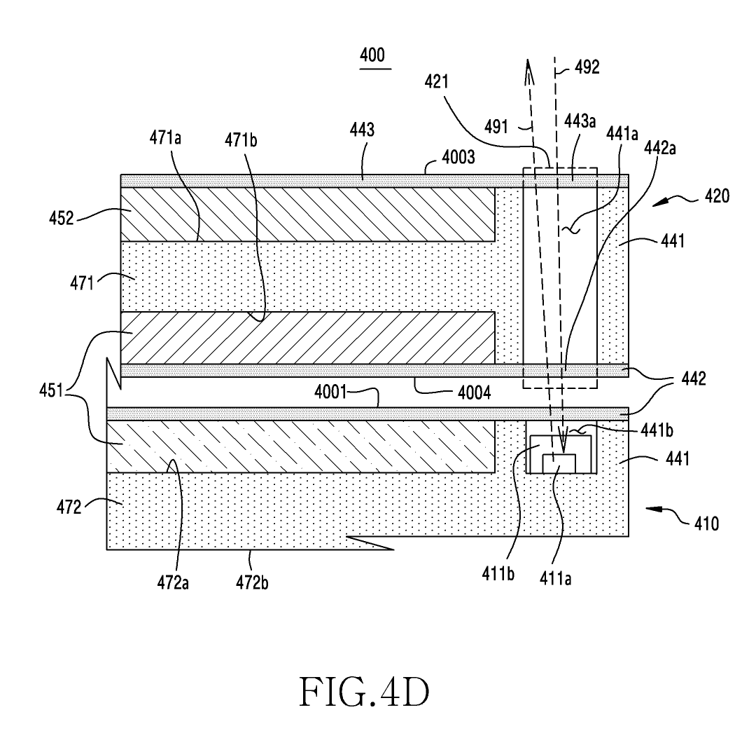

FIGS. 4A and 4B illustrate an unfolded state of an electronic device according to various embodiments of the disclosure.

FIG. 4C illustrates a folded state of the electronic device of FIG. 4A according to an embodiment of the disclosure.

FIG. 4D is a cross-sectional view schematically illustrating the folded state of the electronic device of FIG. 4A according to an embodiment of the disclosure.

Referring to FIGS. 4A and 4B, an electronic device 400 (for example, the electronic device 101 of FIG. 1 or the electronic device 200 of FIG. 2A) is a flexible plate including both surfaces 4010A and 4010B disposed on opposite sides, and may include a first region 410 (for example, the first region 210 of FIG. 2A or 2B), a second region 420 (for example, the second region 220 of FIG. 2A or 2B), and a bendable region 430 (for example, the bendable region 230 of FIG. 2A or 2B), which can be bent between the first region 410 and the second region 420. The second region 420 may be rotated with respect to the first region 410 by the bendable region 430. At least one of the elements of the electronic device 400 may be the same as or similar to at least one of the elements of the electronic device 200 of FIG. 2A, and a duplicate description thereof will thus be omitted.

The electronic device 400 according to an embodiment may include a housing (not shown) including both surfaces 4010A and 4010B and lateral surfaces (not shown) surrounding the space between both surfaces 4010A and 4010B. According to another embodiment (not shown), the housing may refer to a structure forming a portion of the first surface 4010A, the second surface 4010B, and the lateral surfaces. The first region 410 may include a first surface 4001 and a second surface 4002 disposed on opposite sides, and a first lateral surface (not shown) surrounding at least a portion of the space between the first surface 4001 and the second surface 4002. The second region 420 may include a third surface 4003 and a fourth surface 4004 disposed on opposite sides, and a second lateral surface (not shown) surrounding at least a portion of the space between the third surface 4003 and the fourth surface 4004.

One surface 4010A of the electronic device 400 may include the first surface 4001 (for example, the first surface 2001 of FIG. 2A) included in the first region 410, the third surface 4003 (for example, the third surface 2211a or 2211c of FIG. 2A) included in the second region 420, and a surface 4301 (hereinafter, referred to as a fifth surface) (for example, the surface 2301 of FIG. 2A) included in the bendable region 430. The other surface 4010B of the electronic device 400 may include the second surface 4002 (for example, the second surface 2002 of FIG. 2A) included in the first region 410, the fourth surface 4004 (for example, the fourth surface 2212a or 2212c of FIG. 2A) included in the second region 420, and a surface 4302 (hereinafter, referred to as a sixth surface) (for example, the surface 2302 of FIG. 2A) included in the bendable region 430.

According to an embodiment, the sixth surface 4302 may include a structure 4302a in which a convex and concave pattern is regularly arranged. The sixth surface 4302 having the convex and concave structure 4302a may allow the bendable region 430 to be easily bent into a curve.

According to an embodiment, the one surface 4010A of the electronic device 400 may be formed by a fifth plate (not shown), of which at least a portion is substantially transparent. The fifth plate is an integrated plate forming all of the first surface 4001, the third surface 4003, and the fifth surface 4301, and may be formed with a material such as polyimide and may thus exhibit the flexibility required by the bendable region 430. According to various embodiments, the fifth plate may be designed as a polymer plate including various coating layers.

According to an embodiment, the electronic device 500 may include a fifth display 451 (for example, the display device 160 of FIG. 1) disposed to be exposed through a partial area of the fifth plate. For example, the fifth display 451 may be disposed along the first surface 4001, the third surface 4003, and the fifth surface 4301, and may exhibit the flexibility required by the bendable region 430. According to various embodiments, the fifth display 451 may be coupled to or adjacent to a touch detection circuit, a pressure sensor for measuring an intensity (pressure) of a touch, and/or a digitizer for sensing a stylus pen in a magnetic-field type.

According to some embodiments, the display may be designed to be disposed along the first surface 4001 and the third surface 4003, among the first surface 4001, the third surface 4003, and the fifth surface 4301, in which case the part corresponding to the fifth surface 4301 may be excluded from the fifth plate.

According to an embodiment, the second surface 4002 may be formed by a sixth plate (not shown) of which at least a portion is substantially transparent. The sixth plate may be designed as a polymer plate including various coating layers. According to an embodiment, the electronic device 400 may include a sixth display 452 disposed to be exposed through most parts of the sixth plate. According to various embodiments, the sixth display 452 may be coupled to or adjacent to a touch detection circuit, a pressure sensor for measuring an intensity (pressure) of a touch, and/or a digitizer for sensing a stylus pen in a magnetic-field type. According an embodiment, when it is required to display an image in the unfolded state, the electronic device 400 may selectively activate the fifth display 451, among the fifth display 451 and the sixth display 452.

According to an embodiment, the fourth surface 4004 may be formed by a seventh plate which is substantially opaque. The seventh plate may be formed with, for example, coated or tinted glass, ceramic, polymer, metal (for example, aluminum, stainless steel, or magnesium), or a combination of at least two thereof.

According to an embodiment, the structure 4302a in which the convex and concave pattern is regularly arranged may connect the sixth plate and the seventh plate. According to some embodiments, the structure 4302a in which the convex and concave pattern is regularly arranged, the sixth plate, and the seventh plate may be integrated.

According to various embodiments, although not illustrated, the electronic device 400 may include a lateral bezel structure (a lateral member) forming lateral surfaces that surround the space between the two surfaces 4010A and 4010B. According to some embodiments, the lateral bezel structure and the seventh plate may be integrated, and may be made of the same material.

According to an embodiment, the first region 410 may include a light emitting module 411a and light receiving module 411b disposed in the space around the fifth display 451. The light-emitting module 411a may include a light source such as a LED and a light-receiving module 411b may include a photodiode. In the unfolded state, light output from the light-emitting module 411a may pass through the fifth plate and be emitted to the outside, and external light may pass through the fifth plate and flow into the light-receiving module 411b.

According to an embodiment, the second region 420 may include a light transmission region 421 (for example, the light transmission region 221 of FIG. 2A), and may be aligned with the light-emitting module 411a and the light-receiving module 411b of the first region 410 in the folded state, as illustrated in FIG. 4C.

Referring to FIGS. 4C and 4D, in the folded state, light 491 output from the light-emitting module 411a of the first region 410 may pass through the light transmission region 421 of the second region 420 and be emitted to the outside, and external light 492 may pass through the light transmission region 421 of the second region 420 and flow into the light-receiving module 411b of the first region 410. In the folded state, among the fifth display 451 and the sixth display 452, the sixth display 452 may be located at a position that can be used by the user. According to an embodiment, in the folded state, the electronic device 400 may deactivate the fifth display 451. When it is required to display an image in the folded state, the electronic device 400 may activate the sixth display 452.

Referring to FIG. 4D, the electronic device 400 may include a plate 471 (hereinafter, referred to as a first mid plate) (for example, the support member 222 of FIG. 2A) extending between the third surface 4003 and the fourth surface 4004 from the lateral bezel structure 441. A portion of the fifth display 451 may be coupled to one surface 471a of the first mid plate 471, and the sixth display 452 may be coupled to the other surface 471b of the first mid plate 471. The electronic device 400 may include a plate 472 (hereinafter, referred to as a second mid plate) (for example, the support member 271 of FIG. 2A) extending between the first surface 4001 and the second surface (the second surface 4002 of FIG. 4B) from the lateral bezel structure 441, and a portion of the fifth display 451 may be coupled to one surface 472a of the second mid plate 472. The first region 410 may include a printed circuit board (not shown) electrically connected to the fifth display 451 and the sixth display 452, and the printed circuit board may be coupled to the other surface 472b of the second mid plate 472. A processor, a memory, and/or an interface may be mounted on the printed circuit board. The processor may include one or more of, for example, a central processing unit, an application processor, a graphic processing unit, an image signal processor, a sensor hub processor, and a communication processor. The memory may include, for example, volatile memory or nonvolatile memory. The interface may include, for example, a HDMI, a USB interface, an SD card interface, and/or an audio interface. The interface may electrically or physically connect, for example, the electronic device 400 to an external electronic device, and may include a USB connector, an SD card/MMC connector, or an audio connector.

According to an embodiment, the light transmission region 421 of the second region 420 may include a through hole 441a formed in the lateral bezel structure 441, and a portion 442a of the fifth plate 442 and a portion 443a of the sixth plate 443 arranged in the through hole 441a. The light-emitting module 411a and the light-receiving module 411b may be disposed in the space 441b formed in the lateral bezel structure 441, and may be electrically connected to a printed circuit board (not shown) mounted on the first region 410 through an FPCB. According to another embodiment, the light-emitting module 411a and the light-receiving module 411b may be mounted on the printed circuit board, in which case the lateral bezel structure 441 may be designed to be changed so as to be suitable therefor.

According to various embodiments, the light transmission region 421 may include a lens module (not shown) (for example, the lens module 270 of FIG. 2A). The lens module may be disposed between the fifth plate 442 and the sixth plate 443 and allow the light output from the light-emitting module 411a to substantially pass through the light transmission region 421 and be emitted to the outside. The lens module may be provided in various forms for improving the straightness of light or indicating or changing the direction of light.

According to various embodiments, the electronic device 400 may include at least one of an audio module, a camera module, a key input device, and an indicator. According to some embodiments, the electronic device 400 may omit at least one of the elements (for example, the key input device or the indicator) or further include other elements.

The audio module may include a microphone hole and a speaker hole. The microphone hole may include a microphone therein to acquire an external sound, and may include a plurality of microphones to detect the direction of the sound according to some embodiments. The speaker hole may include an external speaker hole and a receiver hole 424 for a call. According to some embodiments, the speaker hole and the microphone hole may be implemented as one hole, or a speaker may be included without the speaker hole (for example, a piezo speaker).

The camera module may include a camera device 413 and/or a flash 412 disposed on the fourth surface 4004 of the electronic device 400. The camera device 413 may include one or a plurality of lenses, an image sensor, and/or an image signal processor. The flash 412 may include, for example, a -LED or a xenon lamp. According to some embodiments, two or more lenses (wide angle and telephoto lenses) and image sensors may be disposed on one side of the electronic device 400. According to various embodiments, the camera module may further include a camera device (not shown) disposed on the second surface 4002.

The key input device (not shown) may include a key button and a touch pad (or a touch key) disposed on the housing 4010. According to another embodiment, the electronic device 400 may not include some or all of the key input devices, and the key input device which is not included may be implemented in a different form, such as a soft key, on the display 451 or 452.

The indicator 426 may be disposed on, for example, the second surface 4002 of the housing 4010. The indicator 426 may provide, for example, status information of the electronic device 400 in the form of light, and may include an LED.

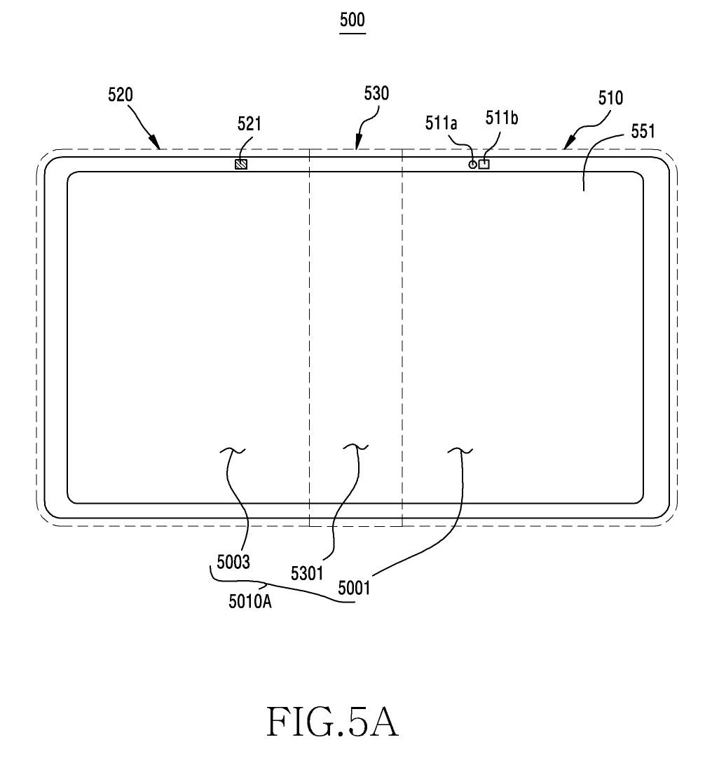

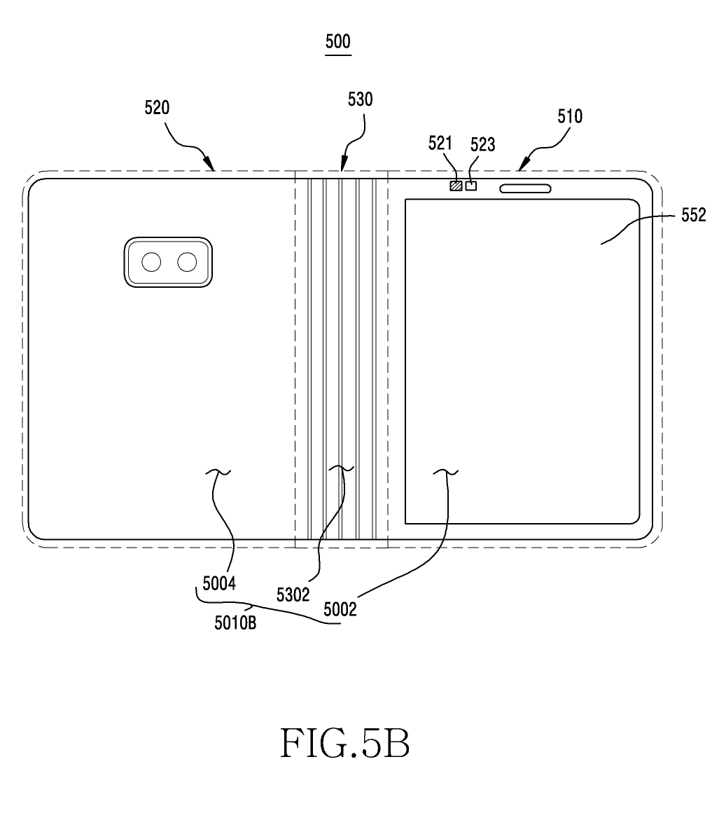

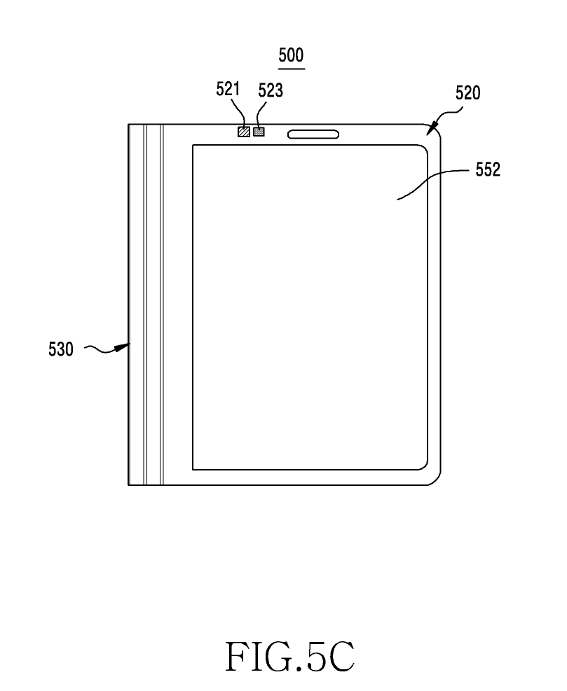

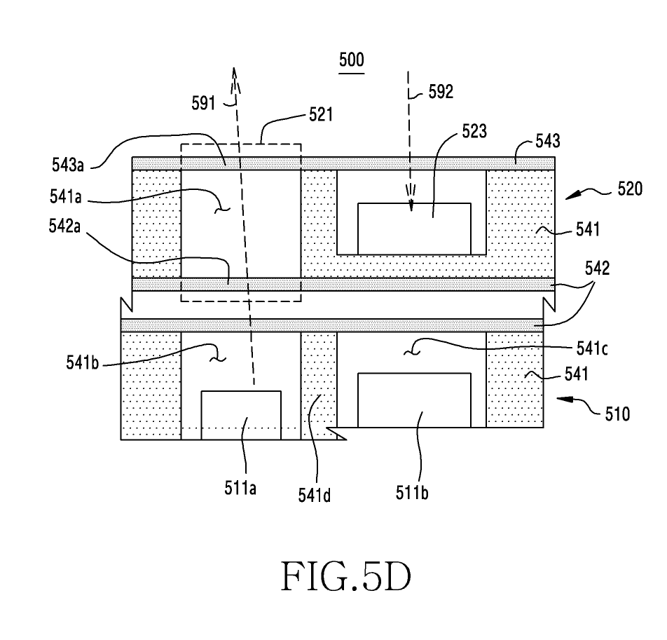

FIGS. 5A and 5B illustrate an unfolded state of an electronic device according to various embodiments of the disclosure.

FIG. 5C illustrates a folded state of the electronic device of FIG. 5A according to an embodiment of the disclosure.

FIG. 5D is a cross-sectional view schematically illustrating the folded state of the electronic device of FIG. 5A according to an embodiment of the disclosure.

Referring to FIGS. 5A and 5B, an electronic device 500 (for example, the electronic device 101 of FIG. 1 or the electronic device 200 of FIG. 2A) is a flexible plate including both surfaces 5010A and 5010B substantially disposed on opposite sides, and may include a first region 510 (for example, the first region 210 of FIG. 2A or 2B), a second region 520 (for example, the second region 220 of FIG. 2A or 2B), and a bendable region 530 (for example, the bendable region 230 of FIG. 2A or 2B), which can be bent between the first region 510 and the second region 520 according to an embodiment. At least one of the elements of the electronic device 500 may be the same as or similar to at least one of the elements of the electronic device 200 of FIG. 2A or the electronic device 400 of FIG. 4A or 4B, and a duplicate description thereof will thus be omitted.

The electronic device 500 according to an embodiment may include a housing (not shown) including both surfaces 5010A and 5010B and lateral surfaces (not shown) surrounding the space between both surfaces 5010A and 5010B. One surface 5010A of the electronic device 500 may include a first surface 5001 (for example, the first surface 2001 of FIG. 2A) included in the first region 510, a third surface 5003 (for example, the third surface 2003 of FIG. 2A) included in the second region 520, and a surface 5301 (hereinafter, referred to as a fifth surface) (for example, the surface 2301 of FIG. 2A) included in the bendable region 530. The other surface 5010B of the electronic device 500 may include a second surface 5002 (for example, the second surface 2002 of FIG. 2A) included in the first region 510, a fourth surface 5004 (for example, the fourth surface 2004 of FIG. 2A) included in the second region 520, and a surface 5302 (hereinafter, referred to as a sixth surface (for example, the surface 2302 of FIG. 2A) included in the bendable region 530.

According to an embodiment, the one surface 5010A of the electronic device 500 may be formed by an integrated fifth plate (not shown) of which at least a portion is substantially transparent, and the electronic device 500 may include a fifth display 551, disposed to be exposed through most parts of the fifth plate. According to an embodiment, the second surface 5002 may be formed by a sixth plate (not shown), of which at least a portion is substantially transparent, and the electronic device 500 may include a sixth display 552 disposed to be exposed through most parts of the sixth plate. According to an embodiment, the fourth surface 5004 may be formed by a seventh plate (not shown), which is substantially opaque. Although not illustrated, the electronic device 500 may include a lateral bezel structure (or a lateral member) forming lateral surfaces that surround the space between both surfaces 5010A and 5010B.

According to an embodiment, the first region 510 may include a light-emitting module 511a and a first light-receiving module 511b disposed in the space around the fifth display 551. The light-emitting module 511a may include a light source such as an LED and the first light-receiving module 511b may include as a photodiode. In the unfolded state, light output from the light-emitting module 511a may pass through the fifth plate and be emitted to the outside, and external light may pass through the fifth plate and flow into the first light-receiving module 511b.

Referring to FIG. 5C, the second region 520 may include a light transmission region 521 (for example, the light transmission region 221 of FIG. 2A), and may be aligned with the light-emitting module 511a and the first light receiving module 511b of the first region 510 in the folded state.

According to an embodiment, the second region 520 may include a second light-receiving module 523 such as a photodiode. Referring to FIGS. 5C and 5D, in the folded state, the electronic device 500 may deactivate the first light-receiving module 511b of the first region 510, and may use the light-emitting module 511a of the first region 510 and the second light-receiving module 523 of the second region 520 when the corresponding sensing mode is executed. In the folded state, light 591 output from the light-emitting module 511a of the first region 510 may pass through the light transmission region 521 and be emitted to the outside, and external light 592 may flow into the second light-receiving module 523 of the second region 520.

According to an embodiment, the first light-receiving module 511b and the second light-receiving module 523 may be designed to support substantially the same sensing mode in the folded state or the unfolded state. For example, at least on the basis of user input and/or an executed application, the second light-receiving module 523 used in the folded state may be configured to receive light of a wavelength band of a particular sensing mode, and the first light-receiving module 511b used in the unfolded state (for example, FIG. 5A) may be configured to receive light of a wavelength band of the same sensing mode.

According to some embodiments, the first light-receiving module 511b and the second light-receiving module 523 may be configured to support different sensing modes according to the folded state or the unfolded state.

According to various embodiments, since the performance can be secured only when an accurate image is focused on the sensor (for example, the first light-receiving module 511b or the second light receiving module 523) in a camera mode or an iris recognition mode, it may be configured to restrict the modes (or executed applications or programs) in the folded state. According to some embodiments, in order to reduce performance deterioration in a particular mode, such as the camera mode or the iris recognition mode, technology for further increasing the transparency of the light transmission region 521 compared to another mode may be applied when the particular mode is executed. For example, the light transmission region 521 may be designed to include an electrochromic medium, and the processor (for example, the processor 120 of FIG. 1) may control the transparency of the light transmission region 521 according to the corresponding mode. According to various embodiments, when an optical sensing mode is not executed, it is possible to improve the aesthetic appearance of the electronic device 500 by reducing the transparency of the light transmission region 521 and thus preventing the light transmission region 521 from being visible.

Referring to FIG. 5D, the light transmission region 521 of the second region 520 may include a through hole 541a formed in the lateral bezel structure 541, a portion 542a of the fifth plate 542 and a portion 543a of the sixth plate 543 being arranged in the through hole 541a. The light-emitting 511a and the first light-receiving module 511b may be disposed in the space 541b and 541c formed in the lateral bezel structure 541, and the space 541b in which the light-emitting module 511a is disposed and the space 541c in which the first light-receiving module 511b is disposed may be separated by the portion 541d of the lateral bezel structure 541.

According to various embodiments, the light transmission region 521 may include a lens module (not shown) (for example, the lens module 270 of FIG. 2A). The lens module may be disposed between the fifth plate 542 and the sixth plate 543 and allow the light output from the light-emitting module 511a to substantially pass through the light transmission region 521 and be emitted to the outside.

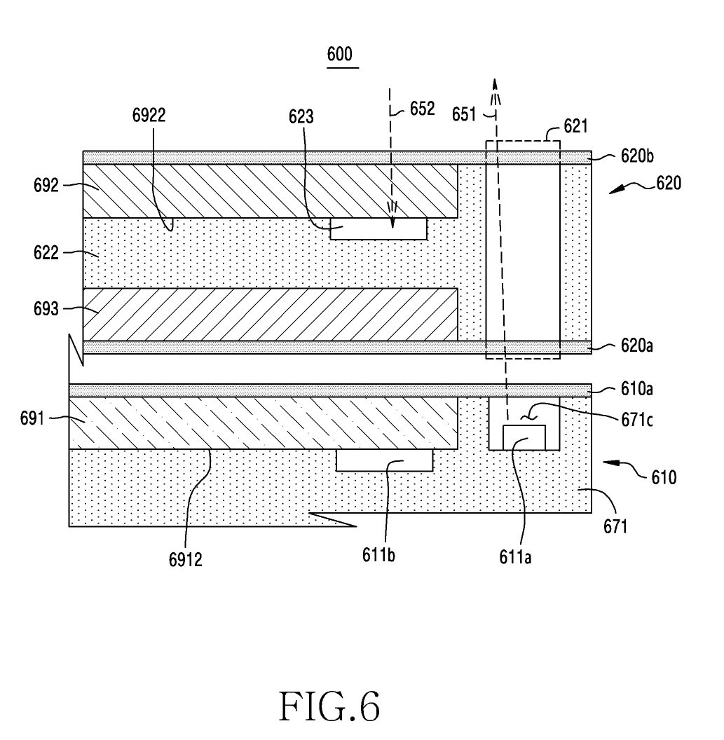

FIG. 6 is a cross-sectional view schematically illustrating a folded state of an electronic device according to an embodiment of the disclosure.

Referring to FIG. 6, an electronic device 600 (for example, the electronic device 101 of FIG. 1 or the electronic device 200 of FIG. 2A) may be in a folded state in which a first region 610 (for example, the first region 210 of FIG. 2A or 2B) and a second region 520 (for example, the second region 220 of FIG. 2A or 2B) overlap each other. At least one of the elements of the electronic device 500 may be the same as or similar to at least one of the elements of the electronic device 200 of FIG. 2A and a duplicate description thereof will thus be omitted. For example, a support member 622 may be the same as or similar to the support member 222 of FIG. 2A or the plate 471 of FIG. 4D.

According to an embodiment, the first region 610 may include a first plate 610a (for example, the first plate 210a of FIG. 2A), a first display 691 (for example, the first display 291 of FIG. 2A), and first optical sensors 611a and 611b (for example, the first optical sensor 211 of FIG. 2A). According to an embodiment, the second region 620 may include a third plate 620a (for example, the third plate 220a of FIG. 2A), a fourth plate 620b (for example, the fourth plate 220b of FIG. 2A), a third display 693 (for example, the third display 293 of FIG. 2A), a second display 692 (for example, the second display 292 of FIG. 2A), a second optical sensor 623 (for example, the second optical sensor 223 of FIG. 2A), and a light transmission region 621 (for example, the light transmission region 221 of FIG. 2A).

According to an embodiment, the first optical sensors 611a and 611b may include a light emitting module disposed in a space 671c formed on a support member 671 (for example, the support member 271 of FIG. 2A) and a receiving module disposed below the rear surface 6912 of the first display 691. According to an embodiment, the second optical sensor 623 may be a light-receiving module disposed below the rear surface 6922 of the second display 692. In the folded state, the electronic device 600 may deactivate the first optical sensor 611b of the first region 610, and when the corresponding sensing mode is executed, may use the first optical sensor 611a of the first region 610 and the second optical sensor 623 of the second region 520. In the folded state, light 651 output from the first optical sensor 611a of the first region 610 may pass through the light transmission region 621 of the second region 620 and be radiated to the outside, and external light 652 may pass through the fourth plate 620b and the second display 692 and flow into the second optical sensor 623.

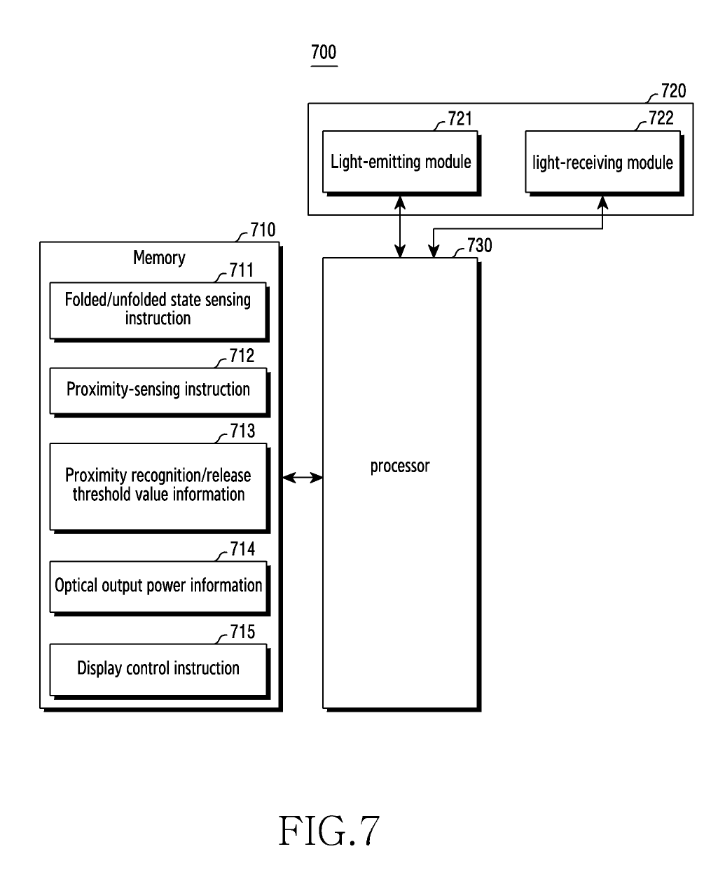

FIG. 7 is a block diagram illustrating an electronic device according to an embodiment of the disclosure.

Referring to FIG. 7, the electronic device 700 may include a memory 710 (for example, the memory 130 of FIG. 1), an optical sensor 720 (for example, the sensor module 176 of FIG. 1), and a processor 730 (for example, the processor 120 of FIG. 1). At least one of the elements of the electronic device 700 may be the same as or similar to at least one of the elements of the electronic device 101 of FIG. 1 or the electronic device 200 of FIG. 2A, and a duplicate description will be omitted. FIG. 7 will be described with reference to FIGS. 1, 2A, 2B, and 2C.

The memory 710 may store data, applications, and algorithms corresponding to various basic operating systems and various user functions required for operating the electronic device 700. The processor 730 may perform various operations of the electronic device 700 on the basis of instructions and information included in the memory 710.

According to an embodiment, the memory 710 may include a folded/unfolded-state-sensing instruction 711, a proximity-sensing instruction 712, proximity recognition/release threshold value information 713, optical output power information 714, or a display control instruction 715.

The folded/unfolded-state-sensing instruction 711 may enable the processor 730 to sense the unfolded state (see FIG. 2B) or the folded state (see FIG. 2A or 2C) of the electronic device 700. According to an embodiment, the folded/unfolded-state-sensing instruction 711 may include a routine for selecting and activating at least one element used for acquiring data on the unfolded state or the folded state. According to an embodiment, the element for acquiring data on the unfolded state or the folded state may be at least a portion of the optical sensor 720, a sensor module (for example, the sensor module 176 of FIG. 1), or a camera. For example, referring to FIG. 2A, the first region 210 may include a hall-effect integrated circuit (IC) (not shown), and the second region 220 may include a member such as a magnet capable of reacting to the hall-effect IC. When the second region 220 rotates and thus enters the first folded state, the member of the second region 220 may be adjacent to the hall IC of the first region 210 and the hall-effect IC may react thereto. When there is reaction of the hall-effect IC, the processor 730 may recognize the first folded state.

According to various embodiments, the element for acquiring data on the unfolded state or the folded state may include at least one sensor coupled to or included in the bendable region 230. For example, an angle sensor or a bending sensor, which is the at least one sensor, may be arranged along at least a portion of the bendable region 230, and may acquire information on the shape of the bendable region 230 (for example, data on a bending degree or a rotating degree) on the basis of a resistance value according to an increase or decrease of the bendable region 230. According to various embodiments, the angle sensor or the bending sensor may be a layer coupled to an external surface 2301 or 2302 of the bendable region 230 or arranged inside the bendable region 230.

According to some embodiments, although not illustrated, the bendable region 230 may include a first member extending from the first region 210 and a second member extending from the second region 220 and thus adjacent to the first member or connected to the first member. At least one sensor may be disposed inside the bendable region 230 to acquire data (for example, a rotation angle) on a mechanical location relationship between the first member and the second member. According to various embodiments, the first member and the second member may be coupled using various mechanical coupling elements (for example, a gear and a hinge) for rotation between the first member and the second member.

Various other sensors may be coupled to or included in at least one of the first region 210, the second region 220, and the bendable region 230 to acquire information on the location relationship between the first region 210, the second region 220 and the shape of the bendable region 230. A sensor equivalent to the at least one sensor described above may be replaced or further included according to a provision form.

The proximity-sensing instruction 712 may cause the processor 730 to determine the proximity of an external object through at least a portion of the optical sensor 720. According to an embodiment, the proximity-sensing instruction 712 may include a routine for selecting and activating at least one light-emitting module 721 and the light-receiving module 722 used by the optical sensor 720 for acquiring a value related to proximity to the external object.

According to an embodiment, the proximity-sensing instruction 712 may include a routine for controlling the optical output power of at least one light-emitting module 721 of the optical sensor 720 on the basis of the unfolded state or the folded state. For example, the light-emitting module 721 may be driven with first optical output power in the unfolded state, and may be driven with second optical output power, higher than the first optical output power, in the folded state. Accordingly, the amount of light (or the intensity of light) passing through the corresponding medium layers and emitted to the outside in the unfolded state and the amount of light passing through the corresponding medium layers and emitted to the outside in the folded state may be constant. Therefore, proximity-sensing performance can be secured at a uniform level both in the unfolded state and in the folded state.

According to an embodiment, the proximity-sensing instruction 712 may include a routine for determining the proximity of the external object on the basis of a proximity recognition threshold value, which is a reference for determining proximity recognition, and a proximity release threshold value, which is a reference for determining proximity release. Light of the proximity-sensing wavelength band scattered or reflected from the external object may flow into the light-receiving module 722. The light-receiving module 722 may generate a sensing value proportional to the amount of flowing light. According to an embodiment, the proximity-sensing instruction 712 may include a routine for determining whether the external object, which is outside a proximity recognition range, moves within the proximity recognition range from the optical sensor 720. According to an embodiment, the proximity-sensing instruction 712 may include a routine for selecting a proximity recognition threshold on the basis of proximity recognition/release threshold value information 713 in the unfolded state or the folded state in the proximity recognition routine. According to an embodiment, the proximity-sensing instruction 712 may include a routine for determining that the external object is within the proximity recognition range when the sensing value generated by the light-receiving module 722 is larger than or equal to the selected proximity recognition threshold value. When the light-emitting module 721 is driven with fixed output power in the folded state and the unfolded state, if a proximity recognition threshold value used in the unfolded state and a proximity recognition threshold value used in the folded state are configured as different values, proximity recognition performance may be secured at a uniform level both in the unfolded state and in the folded state.

According to an embodiment, the proximity-sensing instruction 712 may include a routine for determining whether the external object, which is within a proximity release range, moves outside the proximity release range from the optical sensor 720. The proximity release range may be wider than the proximity recognition range. According to an embodiment, in the proximity release routine, the proximity-sensing instruction 712 may include a routine for selecting a proximity release threshold value on proximity recognition/release threshold value information 713 in the unfolded state or the folded state. The proximity-sensing instruction 712 may include a routine for determining that the external object has moved outside the proximity release range when the sensing value generated by the light-receiving module 722 is smaller than the selected proximity release threshold value. The proximity release threshold value may be smaller than the proximity recognition threshold value. When the light-emitting module 721 is driven with fixed output power in the folded state and the unfolded state, if a proximity release threshold value used in the unfolded state and a proximity release threshold value used in the folded state are configured as different values, proximity release performance may be secured at a uniform level both in the unfolded state and in the folded state.

The proximity recognition/release threshold value information 713 may include a proximity recognition threshold value and a proximity release threshold value based on the unfolded state or the folded state of the electronic device 700. According to an embodiment, the proximity recognition threshold value and the proximity release threshold value included in the proximity recognition/release threshold value information 713 may be digital numbers at the same level as the sensing value generated by the light-receiving module 722. According to various embodiments, the memory 710 may further store an instruction causing the processor 730 to change the proximity recognition/release threshold value information 713 on the basis of user input.

The optical output power information 714 may include an optical output power value based on the unfolded state or the folded state of the electronic device 700. For example, the optical output power value may be a number related to voltage or current. According to various embodiments, the memory 710 may further include an instruction causing the processor 730 to change the optical output power information 714 on the basis of user input.

The display control instruction 715 may cause the processor 730 to select and activate the corresponding display when it is required to display an image on the basis of the unfolded state or the folded state of the electronic device 700. For example, referring to FIG. 2A, when it is required to display an image in the first folded state, the processor 730 may selectively activate the second display 292, among the first display 291, the second display 292, and the third display 293.

According to an embodiment, the display control instruction 715 may include a routine for deactivating the display on the basis of proximity recognition and a routine for activating the display on the basis of recognition release.

According to various embodiments, the memory 710 may further include a function-processing instruction causing the processor 730 to perform various functions of the electronic device 700 on the basis of proximity of the external object. The function-processing instruction may include instructions for performing a function pertaining to proximity of the external object according to the current mode of the electronic device 700 or an executed application.

The optical sensor 720 may include the light-emitting module 721 and the light-receiving module 722, and is at least somewhat similar to the first optical sensor 211 and the second optical sensor 223 illustrated in FIGS. 2A, 2B, and 2C, so a description thereof will be omitted.

According to various embodiments, instructions 711, 712, and 715 and/or information 713 and 714 of the memory 710 may be designed to be stored in the processor 730.

According to some embodiments, the processor 730 may be divided into regions for executing the instructions 711, 712, and 715 of the memory 710. For example, the processor 730 may include a region for sensing the folded/unfolded state, a region for sensing the proximity of the external object, and a region for controlling the display.

The electronic device 700 may further include various elements (or modules) according to a provision form thereof. Since such elements may be variously modified according to the trend toward convergence of digital devices, the elements cannot all be enumerated. However, the electronic device 700 may further include elements equivalent to the aforementioned elements. Further, it should be understood that specific elements among the above-described elements may be excluded or may be replaced with other elements according to the provided form of the electronic device 700 according to the embodiment of the disclosure.

According to an embodiment of the disclosure, an electronic device (for example, the electronic device 101 of FIG. 1, the electronic device 200 of FIG. 2A, or the electronic device 700 of FIG. 7) may include an optical sensor (for example, the sensor module 176 of FIG. 1, the optical sensor 211 of FIG. 2A, or the optical sensor 720 of FIG. 7) including a light-receiving module (for example, the light-receiving module 722 of FIG. 7) and a light-emitting module (for example, the light-emitting module 721 of FIG. 7) and a processor (for example, the processor 120 of FIG. 1 or the processor 730 of FIG. 7) electrically connected to the optical sensor 720. The electronic device 101, 200, or 700 may include a housing including a first region (for example, the first region 210 of FIG. 2A), a second region (for example, the second region 220 of FIG. 2A), and a bendable region (for example, the bendable region 230 of FIG. 2A) connecting the first region 210 and the second region 220, and at least a portion of the optical sensor 176, 211, or 720 in the first region 210 may be exposed through one surface (for example, the first surface 2001 of FIG. 2A) of the first region 210. According to bending of the bendable region 230, in the state in which one surface 2001 of the first region 210 faces one surface of the second region 220 (for example, the third surface 2211a or 2211c of FIG. 2A), a light transmission region (for example, the light transmission region 221 of FIG. 2A) may be included in at least a portion of the second region 220, so that light related to sensing of the optical sensor 176, 211, or 720 passes through the second region 220.

According to an embodiment of the disclosure, at least on the basis of the state in which one surface (for example, the first surface 2001) of the first region 210 faces one surface (for example, the third surface 2211a or 2211c) of the second region 220, the intensity of output of the light-emitting module 721 may be configured to be adjusted.

According to an embodiment, the light transmission region 221 may be located at a portion of the second region 220 aligned with the optical sensor 176, 211, or 720 in the state in which one surface (the first surface 2001) of the first region 210 faces one surface (the third surface 2211a or 2211c) of the second region 220.

According to an embodiment of the disclosure, the electronic device 101, 200, or 700 may include a first display (for example, the first display 291 of FIG. 2A) electrically connected to the processor 120 or 730, and the first display 291 may be disposed in the first region 210 so as to be exposed through the one surface (the first surface 2001) of the first region 210. The electronic device 101, 200, or 700 may include a second display (for example, the second display 292 of FIG. 2A) electrically connected to the processor 120 or 730, and the second display 292 may be exposed through another surface (for example, a portion 2212c of the fourth surface 2212a or 2212c of FIG. 2A) of the second region 220. The processor 120 or 730 may be configured to deactivate the first display 291 at least on the basis of the state in which the one surface (the first surface 2001) of the first region 210 and the one surface (the third surface 2211a or 2211c) of the second region 220 face each other and activate or deactivate the second display 292 at least on the basis of light received by the light-receiving module 722.

According to an embodiment of the disclosure, the processor 120 or 730 may be configured to adjust at least one threshold value for detecting the external object through the optical sensor 176, 211, or 720 at least on the basis of the state in which the one surface (the first surface 2001) of the first region 210 and the one surface (the third surface 2211a or 2211c) of the second region 220 face each other.

According to an embodiment of the disclosure, the light-receiving module 722 may be disposed below a rear surface (for example, the rear surface 2912 of FIG. 2A) of the first display 291.

According to an embodiment of the disclosure, the electronic device 101, 200, or 700 may further include another light-receiving module (for example, the second optical sensor 223 of FIG. 2A) disposed in the second region 220 to be exposed through another surface of the second region 220 (for example, a portion 2212c of the fourth surface 2212a or 2212c of FIG. 2A), electrically connected to the processor 120 or 730, and detecting light, which has been output through the light-emitting module 721 and reflected by the external object.

According to an embodiment of the disclosure, the electronic device 101, 200, or 700 may include the first display 291, which is electrically connected to the processor 120 or 730 and disposed in the first region 210 to be exposed through the one surface (the first surface 2001) of the first region 210, and the second display 292, which is disposed in the second region 220 to be exposed through another surface (the portion 2212c of the fourth surface 2212a or 2212c) of the second region 220. The processor 120 or 730 may be configured to deactivate the first display 291 at least on the basis of the state in which the one surface (the first surface 2001) of the first region 210 and the one surface (the third surface 2211a or 2211c) of the second region 220 face each other and activate or deactivate the second display 292 at least on the basis of light received by the second optical sensor 223.

According to an embodiment of the disclosure, the processor 120 or 730 may control at least one threshold value for detecting the external object through the optical sensor 176, 211, or 720 at least on the basis of the state in which the one surface (the first surface 2001) of the first region 210 and the one surface (the third surface 2211a or 2211c) of the second region 220 face each other.

According to an embodiment of the disclosure, the second optical sensor 223 may be disposed below the second display 292.

According to an embodiment of the disclosure, the processor 120 or 730 may be configured to deactivate the second display 292 at least on the basis of the state in which the one surface (the first surface 2001) of the first region 210 and the one surface (the third surface 2211a or 2211c) of the second region 220 do not face each other and activate or deactivate the first display 291 at least on the basis of light received by the light-receiving module 722.

According to an embodiment of the disclosure, the light transmission region 221 may further include the lens module 270.

According to an embodiment of the disclosure, the light transmission region 221 may include the space 383a or 383b which becomes narrower in a direction from the one surface (the third surface 2211a or 2211c to another surface (the fourth surface 2212a or 2212c) of the second region 220 or in the opposite direction.

According to an embodiment of the disclosure, the electronic device 101, 200, or 700 may include at least one sensor (for example, the sensor module 176 of FIG. 1) for detecting the state in which the one surface (the first surface 2001) of the first region 210 and the one surface (the third surface 2211a or 2211c) of the second region 220 face each other.

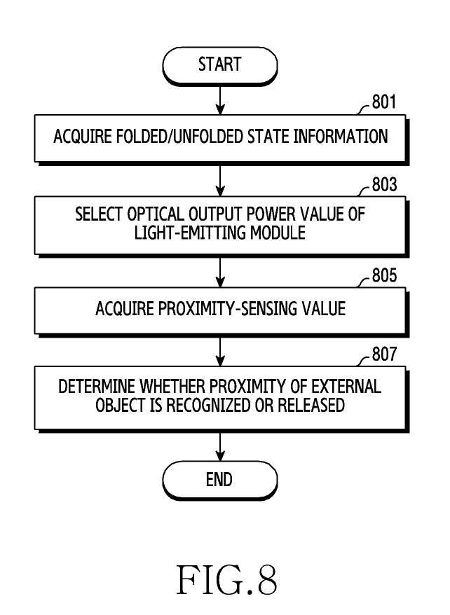

FIG. 8 illustrates a method for determining proximity of an external object according to an embodiment of the disclosure.

Referring to FIG. 8, a method will be described with reference to FIGS. 2A, 2B, and 7. In operation 801, the processor (the processor 120 of FIG. 1 or the processor 730 of FIG. 7) may acquire information on the unfolded state (see FIG. 2B) of the electronic device (the electronic device 101 of FIG. 1 or the electronic device 700 of FIG. 7) or the folded state thereof (the first folded state of FIG. 2A or the second folded state of FIG. 2C). For example, the processor 120 or 730 may acquire information on the unfolded state or the folded state of the electronic device 700 from various elements such as at least a portion of the optical sensor 720, the sensor module 176, or the camera module 180.

Referring to FIG. 2A, the electronic device 101 or 700 may execute a mode (hereinafter, referred to as a pre-mode) for determining the unfolded state or the folded state before executing the corresponding sensing mode. In the pre-mode, the processor 120 or 730 may drive at least one light-emitting module 721 of the optical sensor 720 with power (for example, 5 mA or idle power corresponding thereto) lower than the optical output power used in the corresponding sensing mode. When a sensing value larger than or equal to the corresponding threshold value is generated by at least one light-receiving module 722 of the optical sensor 720, the processor 120 or 730 may determine that the electronic device 101 or 700 is in the folded state. When a sensing value smaller than the corresponding threshold is generated by at least one light-receiving module 722 of the optical sensor 720, the processor 120 or 730 may determine that the electronic device 101 or 700 is in the unfolded state. For example, referring to FIG. 2A, light output from the first optical sensor 211 through the pre-mode may be reflected or scattered from the second region 220 folded on the first region 210 and flow into the first optical sensor 211 in the first folded state.

In operation 803, the processor 120 or 730 may select an optical output power value of the light-emitting module 721 on the basis of the unfolded state or the folded state of the electronic device 101 or 700. According to an embodiment, the processor 120 or 730 may select the optical output power value on the basis of the unfolded state or the folded state of the electronic device 101 or 700 from the optical output power information 714 of the memory 130 or 710.

In operation 805, the processor 120 or 730 may acquire a proximity-sensing value of the external object from the optical sensor 720. According to an embodiment, the light-emitting module 721 may emit light of a proximity-sensing wavelength band, and light scattered or reflected from the external object may be sensed by the light-receiving module 722.

According to an embodiment, although not illustrated, the operation flow of FIG. 8 may further include selecting one or more light-emitting modules and light-receiving modules of the optical sensor 720 according to the unfolded state or the folded state of the electronic device 101 or 700.

In operation 807, the processor 120 or 730 may compare a proximity-sensing value and a proximity recognition threshold value and determine whether the proximity of the external object is recognized on the basis of the comparison result. In operation 807, the processor 120 or 730 may compare a proximity-sensing value and a proximity release threshold value and determine whether the proximity of the external object is released on the basis of the comparison result.

When the proximity of the external object is determined on the basis of the amount of light reflected from the external light in the state configured to use the fixed proximity recognition threshold value and proximity release threshold value, the difference between the proximity-sensing performance in the unfolded state and the folded state due to the difference between medium layers through which light passes may be reduced in the operation flow of FIG. 8.

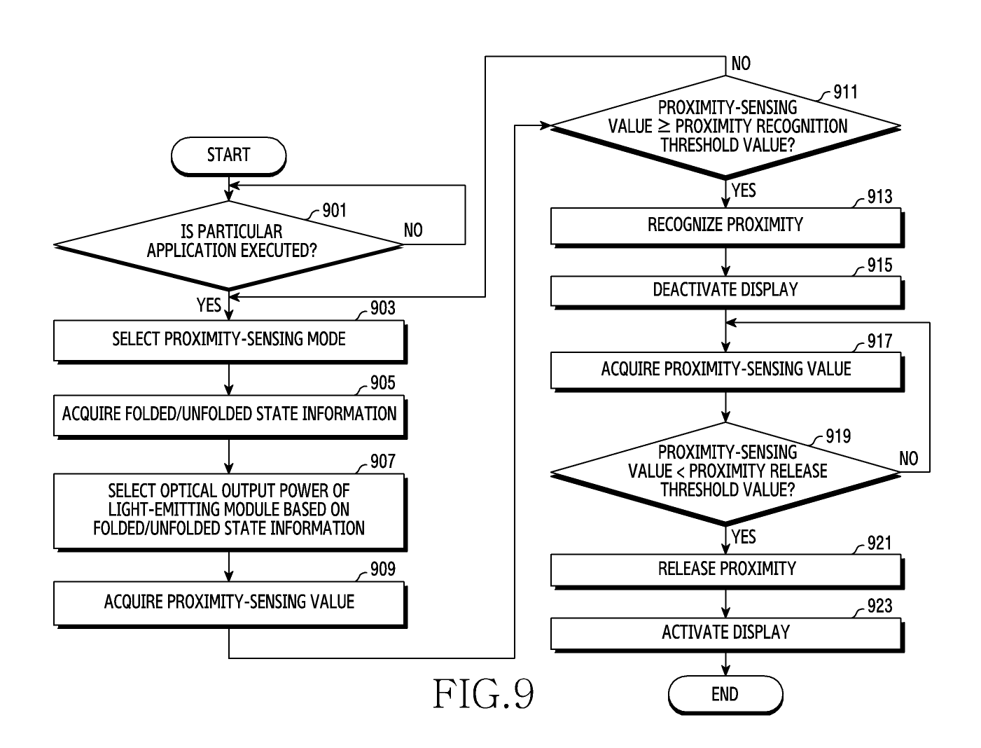

FIG. 9 illustrates a method for determining the proximity of the external object and performing an operation based on the determination result according to an embodiment of the disclosure. FIG. 9 will be described together with FIGS. 1 and 7.

Referring to FIG. 9, a method will be described with reference to FIGS. 1 and 7. When the processor 120 or 730 executes a particular application in operation 901, the processor 120 or 730 may perform operation 903. The particular application may be various applications that can be used by bringing the electronic device 101 or 700 close to a user's body.

According to an embodiment, the particular application may be a call application. During execution of the call application, the electronic device 101 or 700 may be used while being located close to a user's head to make a call. When a call to a phone number of the external device 102 or 104 is requested through user input, the processor 120 or 730 may execute an application related to an outgoing call (hereinafter, referred to as an outgoing call application). The electronic device 101 or 700 may receive a call from the external device, and the processor 120 or 730 may execute an application related to an incoming call (hereinafter, referred to as an incoming call application).

According to an embodiment, the particular application may be an application related to analysis of an object (hereinafter, referred to as an object analysis application). According to various embodiments, the object analysis application may be an application related to biometric sensing (hereinafter, referred to as a biometric sensing application). During execution of the biometric sensing application, the electronic device 101 or 700 may be used while being located close to a user's skin for biometric sensing (of, for example, skin moisture, skin melanin, or red spots on the skin).

In operation 903, the processor 120 or 730 may select a proximity- sensing mode on the basis of execution of the particular application. According to an embodiment, the processor 120 or 730 may control the light-emitting module 721 on the basis of the proximity-sensing mode, and the light-emitting module 721 may output light of a sensing wavelength band corresponding to the proximity-sensing mode. The processor 120 or 730 may control the light-receiving module 722 on the basis of the proximity-sensing mode, and the light-receiving module 722 may activate at least a portion thereof capable of receiving light in the sensing wavelength band corresponding to the proximity-sensing mode.

In operation 905, the processor 120 or 730 may acquire information on the unfolded state or the folded state of the electronic device 101 or 700 from various elements.

In operation 907, the processor 120 or 730 may select an optical output power value of the light-emitting module 721 on the basis of the unfolded state or the folded state of the electronic device 101 or 700.

In operation 909, the processor 120 or 730 may acquire a proximity-sensing value of the external object through the proximity-sensing mode. According to an embodiment, the light-emitting module 721 may emit light of a proximity-sensing wavelength band, and light scattered or reflected from the external object may be sensed by the light-receiving module 722.

According to an embodiment, although not illustrated, the operation flow of FIG. 9 may further include an operation for selecting at least one of one or more light-emitting modules and light-receiving modules of the optical sensor 720 according to the unfolded state or the folded state of the electronic device 101 or 700.

In operation 911, the processor 120 or 730 may compare a proximity-sensing value and a proximity recognition threshold value. When the proximity-sensing value is larger than or equal to the proximity recognition threshold value, the processor 120 or 730 may determine that the external object, which is outside a proximity recognition range, has moved to the proximity recognition range (for example, proximity recognition) in operation 913. When the proximity-sensing value is smaller than the proximity recognition threshold value, the processor 120 or 730 may perform operation 903 again. According to another embodiment, although not illustrated, when the proximity-sensing value is smaller than the proximity recognition threshold value, the processor 120 or 730 may perform operation 909 again in the operation flow.

In operation 915, the processor 120 or 730 may deactivate the corresponding display in response to proximity recognition.

In operation 917, the processor 120 or 730 may acquire a proximity-sensing value of the external object through the proximity-sensing mode.

In operation 919, the processor 120 or 730 may compare a proximity-sensing value and a proximity release threshold value. When the proximity-sensing value is smaller than the proximity release threshold value, the processor 120 or 730 may determine that the external object has moved outside a proximity release range (for example, proximity release recognition) and release the proximity sensing in operation 921. When the proximity-sensing value is larger than or equal to the proximity release threshold value, the processor 120 or 730 may perform operation 917 again.

In operation 923, the processor 120 or 730 may activate the corresponding display in response to proximity release.

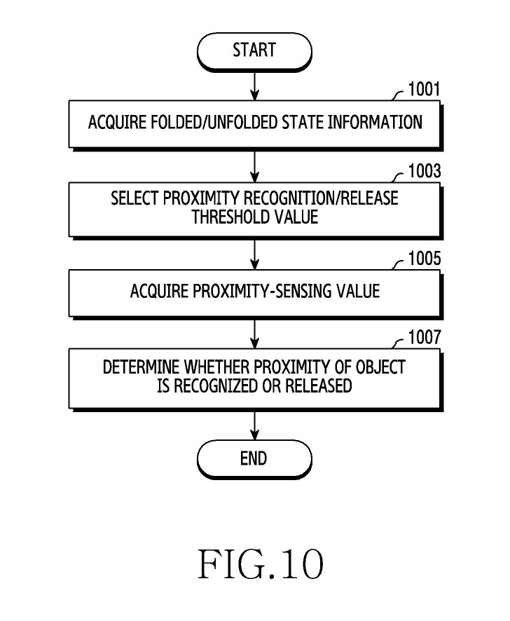

FIG. 10 illustrates a method for determining the proximity of an external object according to an embodiment of the disclosure.

Referring to FIG. 10, a method will be described with reference to FIGS. 1, 2A, 2B, and 7. In operation 1001, the processor 120 or 730 may acquire information on the unfolded state (see FIG. 2B) or the folded state (the first folded state of FIG. 2A or the second folded state of FIG. 2C) of the electronic device 101 or 700. For example, the processor 120 or 730 may acquire information on the unfolded state or the folded state of the electronic device 800 from various elements, such as at least a portion of the optical sensor 720, the sensor module 176, or the camera module 180.

Referring to FIG. 2A, the electronic device 101 or 700 may execute a pre-mode for determining the unfolded state or the folded state before executing the corresponding sensing mode. In the pre-mode, the processor 120 or 730 may drive at least one light-emitting module 721 of the optical sensor 720 with power (for example, 5 mA or idle power corresponding thereto) lower than the optical output power used in the corresponding sensing mode. When a sensing value larger than or equal to the corresponding threshold value is generated in at least one light-receiving module 722 of the optical sensor 720, the processor 120 or 730 may determine that the electronic device 101 or 700 is in the folded state. When a sensing value smaller than the corresponding threshold is generated by at least one light-receiving module 722 of the optical sensor 720, the processor 120 or 730 may determine that the electronic device 101 or 700 is in the unfolded state. For example, referring to FIG. 2A, in the first folded state, light output from the first optical sensor 211 through the pre-mode may be reflected or scattered from the second region 220, folded on the first region 210, and flow into the first optical sensor 211.

In operation 1003, the processor 120 or 730 may select a proximity recognition threshold value and a proximity recognition release threshold value on the basis of the unfolded state or the folded state of the electronic device 101 or 700. According to an embodiment, the processor 120 or 730 may select a proximity recognition threshold value and a proximity recognition release threshold value on the basis of the unfolded state or the folded state of the electronic device 101 or 700 from the proximity recognition/release threshold value information 713 of the memory 130 or 710.

In operation 1005, the processor 120 or 700 may acquire a proximity-sensing value of the external object from the optical sensor 720. According to an embodiment, the light-emitting module 721 may emit light of a proximity-sensing wavelength band, and light scattered or reflected from the external object may be sensed by the light-receiving module 722.

According to an embodiment, although not illustrated, the operation flow of FIG. 10 may further include selecting one or more light-emitting modules and light-receiving modules of the optical sensor 720 according to the unfolded state or the folded state of the electronic device 101 or 700.

In operation 1007, the processor 120 or 730 may compare a proximity-sensing value and a proximity recognition threshold value and determine whether proximity of the external object is recognized on the basis of the comparison result. According to an embodiment, when a proximity-sensing light source is configured to be driven with fixed optical output power, the processor 120 or 730 may compare a proximity-sensing value generated by the light-receiving module 722 with a proximity recognition threshold value selected on the basis of the folded/unfolded state and determine whether the external object, which is outside the proximity recognition range, moves within the proximity recognition range.

In operation 1007, the processor 120 or 730 may compare a proximity-sensing value and a proximity release threshold value and determine whether the proximity of the external object is released on the basis of the comparison result. According to an embodiment, when a proximity-sensing light source is configured to be driven with fixed optical output power, the processor 120 or 730 may compare a proximity-sensing value generated by the light-receiving module 722 with a proximity release threshold value selected on the basis of the folded/unfolded state and determine whether the external object, which is outside the proximity release range, moves within the proximity release range.

When the proximity of the external object is determined on the basis of the amount of light reflected from the external object in the state in which the proximity-sensing light source is configured to be driven with the fixed optical output power, the difference between proximity-sensing performance in the unfolded state and the folded state due to the difference between medium layers through which light passes may be reduced in the operation flow of FIG. 10.

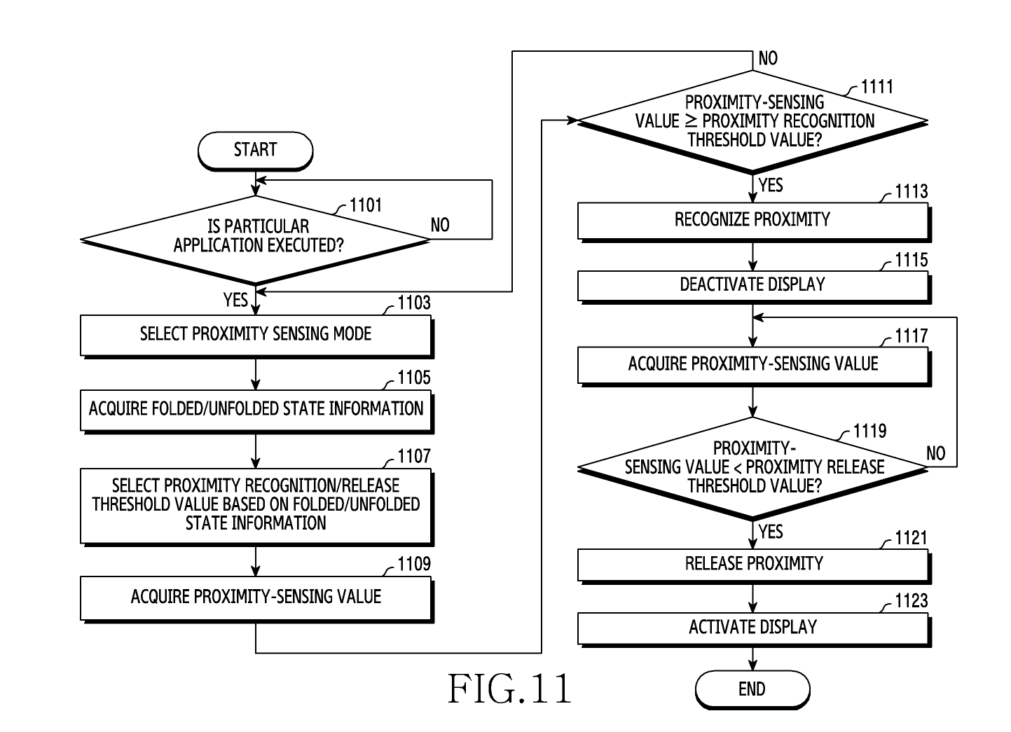

FIG. 11 illustrates a method for determining proximity of an external object according to an embodiment of the disclosure. FIG. 11 will be described together with FIGS. 1 and 7.

Referring to FIG. 11, a method will be described with reference to FIGS. 1 and 7. When the processor 120 or 730 executes a particular application in operation 1101, the processor 120 or 730 may perform operation 1103. The particular application may be various applications that can be used by bringing the electronic device 101 or 700 close to a user's body. For example, the particular application may be a call application, an object analysis application, or a biometric sensing application.

In operation 1103, the processor 120 or 730 may select a proximity-sensing mode on the basis of execution of the particular application. According to an embodiment, the processor 120 or 730 may control the light-emitting module 721 on the basis of the proximity-sensing mode, and the light-emitting module 721 may output light of a sensing wavelength band corresponding to the proximity-sensing mode. The processor 120 or 730 may control the light-receiving module 722 on the basis of the proximity-sensing mode, and the light-receiving module 722 may activate at least a portion thereof capable of receiving light in a sensing wavelength band corresponding to the proximity-sensing mode.

In operation 1105, the processor 120 or 730 may acquire information on the unfolded state or the folded state of the electronic device 101 or 700 from various elements.

In operation 1107, the processor 120 or 730 may select a proximity recognition threshold value and a proximity release threshold value on the basis of the unfolded state or the folded state of the electronic device 101 or 700.

In operation 1109, the processor 120 or 730 may acquire a proximity-sensing value of the external object through the proximity-sensing mode. According to an embodiment, the light-emitting module 721 may emit light in a proximity-sensing wavelength band, and light scattered or reflected from the external object may be sensed by the light-receiving module 722.

According to an embodiment, although not illustrated, the operation flow of FIG. 11 may further include an operation for selecting at least one of one or more light-emitting modules and light-receiving modules of the optical sensor 720 according to the unfolded state or the folded state of the electronic device 101 or 700.

In operation 1111, the processor 120 or 730 may compare a proximity-sensing value and a proximity recognition threshold value. When the proximity-sensing value is larger than or equal to the proximity recognition threshold value, the processor 120 or 730 may determine that the external object, which is outside a proximity recognition range, has moved into the proximity recognition range (for example, recognizes the proximity thereof) in operation 1113. When the proximity-sensing value is smaller than the proximity recognition threshold value, the processor 120 or 730 may perform operation 1103 again. According to another embodiment, although not illustrated, when the proximity-sensing value is smaller than the proximity recognition threshold value, the processor 120 or 730 may perform operation 1109 again in the operation flow.

In operation 1115, the processor 120 or 730 may deactivate the corresponding display in accordance with proximity recognition.

In operation 1117, the processor 120 or 730 may acquire a proximity-sensing value of the external object through the proximity-sensing mode.

In operation 1119, the processor 120 or 730 may compare a proximity-sensing value and a proximity release threshold value. When the proximity-sensing value is smaller than the proximity release threshold value, the processor 120 or 730 may determine that the external object has moved outside a proximity release range (for example, proximity release recognition) in operation 1121. When the proximity-sensing value is larger than or equal to the proximity release threshold value, the processor 120 or 730 may perform operation 1117 again.

In operation 1123, the processor 120 or 730 may activate the corresponding display in response to proximity release.

According to an embodiment of the disclosure, a method of operating an electronic device may include an operation of outputting light of at least one wavelength band through a light-emitting module located in a first region of the electronic device, an operation of receiving at least a portion of light scattered or reflected from an external object through a light-receiving module located in a second region of the electronic device separate from the first region, and an operation of controlling the intensity of output of the light-emitting module based at least on the state in which the first region and the second region face each other or at least one threshold value for determining the proximity of the external object through the light-emitting module. The light-emitting module may be aligned with a light transmission region of the second region in the state in which the first region and the second region face each other.

According to an embodiment of the disclosure, the method may further include an operation of, when the intensity of the output of the light-emitting module is controlled, fixing the at least one threshold value to a set value.

According to an embodiment of the disclosure, the method may further include an operation of, when the at least one threshold value is controlled, fixing the intensity of the output of the light-emitting module to a set value.

According to an embodiment of the disclosure, the method may further include an operation of, in the state in which the first region and the second region face each other, deactivating a first display included in the first region and activating or deactivating a second display included in the second region based on a value corresponding to a light received by the light-receiving module.

According to an embodiment of the disclosure, the method may further include an operation of, in the state in which the first region and the second region do not face each other, deactivating the second display and activating or deactivating the first display based on a value corresponding to a light received by a second light-receiving module included in the first region.

The disclosure has been described above in connection with the various embodiments thereof. It will be understood by those skilled in the art to which the disclosure belongs that the disclosure may be implemented in modified forms without departing from the essential characteristics of the disclosure. Therefore, the embodiments disclosed herein should be considered from an illustrative point of view, rather than a limitative point of view. The scope of the disclosure is found not in the above description but in the accompanying claims, and all differences falling within the scope equivalent to the claims should be construed as being included in the disclosure.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
an optical sensor including a light-receiving module and a light-emitting module;
a processor; and
a housing including a first region, a second region, and a bendable region connecting the first region and the second region, the housing being disposed such that the optical sensor in the first region is exposed through a first surface of the first region,
wherein the second region includes a light transmission region to pass light to the optical sensor when the first surface of the first region and a second surface of the second region face each other based on a bending of the bendable region.

2. The electronic device of claim 1, wherein the processor is configured to control an intensity of output of the light-emitting module based on whether the first surface of the first region and the second surface of the second region face each other.

3. The electronic device of claim 1, wherein the light transmission region is aligned with the optical sensor when the first surface of the first region and the second surface of the second region face each other.

4. The electronic device of claim 1, further comprising:
a first display disposed in the first region and exposed through a surface of the first region; and
a second display disposed in the second region and exposed through another surface of the second region,
wherein the processor is configured to:
deactivate the first display based on whether the first surface of the first region and the second surface of the second region face each other, and
activate or deactivate the second display based on light received by the light-receiving module.

5. The electronic device of claim 1, wherein the processor is configured to control a threshold value for detecting an external object through the optical sensor based on whether the first surface of the first region and the second surface of the second region face each other.

6. The electronic device of claim 4, wherein the light-receiving module is disposed below the first display.

7. The electronic device of claim 1, further comprising a second light-receiving module located on another surface of the second region and configured to detect light output through the light-emitting module and reflected by an external object.

8. The electronic device of claim 7, further comprising:
a first display disposed in the first region and exposed through the first surface of the first region; and
a second display disposed in the second region and exposed through another surface of the second region,
wherein the processor is configured to:
deactivate the first display based on whether the first surface of the first region and the second surface of the second region face each other, and
activate or deactivate the second display based at least on light received by the second light-receiving module.

9. The electronic device of claim 7, wherein the processor is configured to control a threshold value for detecting the external object through the optical sensor based on whether the first surface of the first region and the second surface of the second region face each other.

10. The electronic device of claim 8, wherein the second light-receiving module is disposed below the second display.

11. The electronic device of claim 8, wherein the processor is further configured to:
deactivate the second display based on whether the first surface of the first region and the second surface of the second region face each other, and
activate or deactivate the first display based at least on the light received by the light-receiving module.

12. The electronic device of claim 1, wherein the light transmission region includes a lens module.

13. The electronic device of claim 12, wherein the lens module is configured to focus light passing through the light transmission region on the light-receiving module.

14. The electronic device of claim 1, wherein the light transmission region includes a space which becomes narrower in a direction from the second surface of the second region to another surface of the second region.

15. The electronic device of claim 1, further comprising at least one sensor for detecting whether the first surface of the first region and the second surface of the second region face each other.

16. The electronic device of claim 1, wherein the optical sensor includes a proximity sensor.

17. A method of operating an electronic device, the method comprising:
outputting a light of at least one wavelength through a light-emitting module located in a first region of the electronic device;
when the light is output, receiving light that is reflected by an external object through a light-receiving module located in a second region of the electronic device, which is separate from the first region; and
controlling an intensity of output of the light-emitting module based on whether the first region and the second region face each other or a threshold value for determining a proximity of the external object,
wherein the light-emitting module is aligned with a light transmission region of the second region when the first region and the second region face each other.

18. The method of claim 17, further comprising, when the intensity of the output of the light-emitting module is controlled, fixing the threshold value to a set value.

19. The method of claim 17, further comprising, when the threshold value is controlled, fixing the intensity of the output of the light-emitting module to a set value.

20. The method of claim 17, further comprising, when the first region and the second region face each other, deactivating a first display included in the first region and activating a second display included in the second region based on an amount of light received by the light-receiving module.

21. The method of claim 20, further comprising, when the first region and the second region do not face each other, deactivating the second display and activating the first display based on an amount of light received by a second light-receiving module.
